(19) United States
(12) Patent Application Publication
(10) Pub. No.: US 2026/0032383 A1
(43) Pub. Date: Jan. 29, 2026

(54) AUDIO PLAYING MODULE AND AUDIO PROCESSING CIRCUIT THEREOF, AND ELECTRONIC DEVICE

(71) Applicants: BEIJING BOE DISPLAY TECHNOLOGY CO., LTD., Beijing (CN); BOE TECHNOLOGY GROUP CO., LTD., Beijing (CN)

(72) Inventors: Wenyu LI, Beijing (CN); Jian ZHANG, Beijing (CN); Shou LI, Beijing (CN); Jing ZHANG, Beijing (CN); Mingming YANG, Beijing (CN); Yingbo GAO, Beijing (CN); Zhengyan WAN, Beijing (CN)

(73) Assignees: BEIJING BOE DISPLAY TECHNOLOGY CO., LTD., Beijing (CN); BOE TECHNOLOGY GROUP CO., LTD., Beijing (CN)

(21) Appl. No.: 18/995,913

(22) PCT Filed: Mar. 15, 2024
(86) PCT No.: PCT/CN2024/081936

§ 371 Date: Jan. 17, 2025

(30) Foreign Application Priority Data
Mar. 15, 2023 (CN) 202320539991.5
Jul. 31, 2023 (CN) 202310952201.0
Jul. 31, 2023 (CN) 202322038057.8
Mar. 14, 2024 (CN) 202410296379.9

(51) Int. Cl. H04R 3/02; H03F 3/183; H04R 3/00

(52) U.S. Cl. CPC H04R 3/02; H03F 3/183; H04R 3/007; H03F 2200/03

(57) ABSTRACT

Provided are an audio playing module and an audio processing circuit thereof, and an electronic device, which belong to the technical field of electronics. In the audio processing circuit, by adding a feedback control circuit between a power circuit and an audio amplifier, the feedback control circuit can control, according to a change in the amplitude of an audio signal received by the audio amplifier, the power circuit to adjust a power supply voltage provided for the audio amplifier. Thus, when the amplitude of the audio signal changes, an appropriate power supply voltage can be matched for the audio amplifier by means of the feedback control circuit, thereby solving the problem of the audio playing module generating whistling when the amplitude of the audio signal changes, and thus optimizing the sound quality of played sounds.

This application is a US national stage of international application No. PCT/CN2024/081936, filed on Mar. 15, 2024, which claims priority to Chinese Patent Application No. 202320539991.5, filed on Mar. 15, 2023 and entitled “AUDIO AMPLIFIER CIRCUIT,” Chinese Patent Application No. 202310952201.0 filed on Jul. 31, 2023 and entitled “AUDIO PLAYBACK MODULE, AND AUDIO PROCESSING CIRCUIT AND ELECTRONIC DEVICE THEREFOR,” and Chinese Patent Application No. 202322038057.8 filed on Jul. 31, 2023 and entitled “AUDIO PLAYBACK MODULE, AND AUDIO PROCESSING CIRCUIT AND ELECTRONIC DEVICE THEREFOR,” the contents which are incorporated herein by reference in their entireties.

### TECHNICAL FIELD

The present disclosure relates to the technical field of electronics, and in particular, relates to an audio playback module, an audio processing circuit, and an electronic device.

### BACKGROUND

With the development of the Internet of things (IoT) and smart home technologies, human-computer interaction has been realized in small household appliances by adding liquid crystal displays (LCDs) and speakers to the products. As market demand expands, additional functionality such as video playback and voice guidance has been achieved by adding a system board that integrates images, audio, and video onto traditional LCD modules.

In the above-mentioned system board, a class D audio power amplifier is primarily used to drive the audio playback assembly for sound reproduction. Although class D audio power amplifiers have advantages such as small size and high power, their characteristics, including susceptibility to potential fluctuations and the lack of an independently regulatable power supply, may lead to howling during playback. Thus, audio playback using class D audio power amplifiers still suffers from poor audio quality.

### SUMMARY

Embodiments of the present disclosure provide an audio playback assembly, an audio processing circuit, and an electronic device. The technical solutions are as follows:

In one aspect of the embodiments of the present disclosure, an audio processing circuit is provided. The audio processing circuit includes an audio amplifier, a feedback control circuit, and a power supply circuit; where
the feedback control circuit is connected to an input terminal of the audio amplifier and an input terminal of the power supply circuit, and an output terminal of the power supply circuit is connected to a power terminal of the audio amplifier; and
the feedback control circuit is configured to control, based on an audio signal received at the input terminal of the audio amplifier, the power supply circuit to regulate a supply voltage provided to the power terminal of the audio amplifier, and a magnitude of the supply voltage upon regulation is positively correlated with an amplitude of the audio signal.

In some embodiments, the feedback control circuit is configured to regulate an input voltage at the input terminal of the power supply circuit based on the audio signal, where a magnitude of the input voltage upon regulation is negatively correlated with the amplitude of the audio signal; and
the power supply circuit is configured to regulate, based on the input voltage upon regulation, the supply voltage provided to the power terminal of the audio amplifier.

In some embodiments, the feedback control circuit is connected to the output terminal of the power supply circuit and a feedback terminal of the power supply circuit, and is further configured to feed back the supply voltage provided by the power supply circuit to the power terminal of the audio amplifier to the feedback terminal of the power supply circuit; and the feedback control circuit includes a control sub-circuit and a feedback sub-circuit; and where
the control sub-circuit is connected to the input terminal of the power supply circuit via the feedback sub-circuit, the control sub-circuit is further connected to the input terminal of the audio amplifier, and the feedback sub-circuit is further connected to the output terminal of the power supply circuit and the feedback terminal of the power supply circuit;
the control sub-circuit is configured to regulate the input voltage at the input terminal of the power supply circuit based on the audio signal; and
the feedback sub-circuit is configured to feed back the supply voltage provided by the power supply circuit to the power terminal of the audio amplifier to the feedback terminal of the power supply circuit.

In some embodiments, the control sub-circuit includes a first resistor and a first transistor; and
one terminal of the first resistor is connected to the input terminal of the audio amplifier, another terminal of the first resistor is connected to a control electrode of the first transistor, a first electrode of the first transistor is connected to the input terminal of the power supply circuit via the feedback sub-circuit, and a second electrode of the first transistor is grounded.

In some embodiments, the feedback sub-circuit includes a first feedback sub-circuit and a second feedback sub-circuit;
a first terminal of the first feedback sub-circuit is connected to the output terminal of the power supply circuit; a second terminal of the first feedback sub-circuit is connected to the feedback terminal of the power supply circuit; and a third terminal of the first feedback sub-circuit is connected to the control sub-circuit, the second feedback sub-circuit, and the input terminal of the power supply circuit; and
a magnitude of a current of the control sub-circuit is positively correlated with the amplitude of the audio signal, a magnitude of a current of the second feedback sub-circuit is negatively correlated with the magnitude of the current of the control sub-circuit, and the input voltage at the input terminal of the power supply circuit is positively correlated with the magnitude of the current of the second feedback sub-circuit.

In some embodiments, the first feedback sub-circuit includes a second resistor, a third resistor, and a first capacitor; and the second feedback sub-circuit includes a fourth resistor; and
one terminal of the second resistor is connected to the output terminal of the power supply circuit; another terminal of the second resistor is connected to one terminal of the first capacitor, one terminal of the fourth resistor, the control sub-circuit, and the input terminal of the power supply circuit; another terminal of the first capacitor is connected to a terminal of the third resistor; another terminal of the third resistor is connected to the feedback terminal of the power supply circuit; and another terminal of the fourth resistor is grounded.

In some embodiments, the audio processing circuit further includes a controller; an output terminal of the controller is connected to the input terminal of the audio amplifier, and the output terminal of the power supply circuit is further connected to a power terminal of the controller;
the power supply circuit is further configured to provide the supply voltage to the power terminal of the controller;
the controller is further configured to generate the audio signal based on a stored digital signal, and output the audio signal to the input terminal of the audio amplifier in the case of power-on; and
the audio amplifier is configured to drive, based on the audio signal, a connected audio playback assembly to play audio in the case of power-on.

In some embodiments, the audio processing circuit further includes a power-on protection circuit, connected between the output terminal of the power supply circuit and the audio amplifier; and
where the power-on protection circuit is configured to control the audio amplifier to be powered on in the case of power-on of the controller.

In some embodiments, the power-on protection circuit is connected to an enable terminal of the audio amplifier;
the power-on protection circuit is configured to perform voltage division on the supply voltage provided by the power supply circuit to the power terminal of the audio amplifier, and output a divided voltage to the enable terminal of the audio amplifier to power on the audio amplifier; and
the audio amplifier is configured to drive, based on the audio signal, the audio playback assembly to play back the audio in a case that a voltage at the enable terminal of the audio amplifier is greater than an enable voltage threshold; and
where a duration for which the voltage at the enable terminal is greater than the enable voltage threshold is greater than or equal to a duration required for the controller to enter a stable operating state.

In some embodiments, the power-on protection circuit includes a passive integrator, and the passive integrator includes a fifth resistor and a second capacitor; one terminal of the fifth resistor is connected to the output terminal of the power supply circuit, another terminal of the fifth resistor is connected to one terminal of the second capacitor and an enable terminal of the power supply circuit, and another terminal of the second capacitor is grounded; or
the power-on protection circuit includes an active integrator, and the active integrator includes a sixth resistor, a seventh resistor, an eighth resistor, a third capacitor, and a first operational amplifier; and one terminal of the sixth resistor is connected to the output terminal of the power supply circuit, another terminal of the sixth resistor is connected to one terminal of the seventh resistor and a non-inverting input terminal of the first operational amplifier, another terminal of the seventh resistor is connected to one terminal of the eighth resistor and is grounded, another terminal of the eighth resistor is connected to an inverting input terminal of the first operational amplifier and one terminal of the third capacitor, another terminal of the third capacitor is connected to an output terminal of the first operational amplifier, and the output terminal of the first operational amplifier is further connected to an enable terminal of the power supply circuit.

In some embodiments, the power terminal of the power supply circuit is connected to a power supply, and the power supply circuit is further configured to provide the supply voltage to the power terminal of the audio amplifier and the power terminal of the controller based on a power signal provided by the power supply;
the audio processing circuit further includes a brown-out protection circuit, connected between the power supply and the audio amplifier;
the brown-out protection circuit is configured to control the audio amplifier to be powered down prior to power-down of the controller in the case that the power supply stops providing the power signal; and
the audio amplifier is configured to stop driving the audio playback assembly to play audio in the case of power-down.

In some embodiments, the brown-out protection circuit is connected to an enable terminal of the audio amplifier; and
the brown-out protection circuit is configured to control a voltage at the enable terminal of the audio amplifier to be less than an enable voltage threshold to power down the audio amplifier in the case that a voltage of the power signal provided by the power supply is less than a supply voltage threshold.

In some embodiments, the brown-out protection circuit includes a first branch, a second branch, and a third branch;
one terminal of the first branch is connected to the power supply; one terminal of the second branch is connected to the one terminal of the first branch; one terminal of the third branch is connected to the one terminal of the second branch; another terminal of the first branch, another terminal of the second branch, and another terminal of the third branch are all grounded; and the third branch is further connected to the enable terminal of the audio amplifier;
the first branch is configured to output a first control voltage to the second branch based on the power signal provided by the power supply;
the second branch is configured to output a second control voltage to the third branch based on the first control voltage; and
the third branch is configured to control the voltage at the enable terminal of the audio amplifier based on the second control voltage.

In some embodiments, the first branch includes a ninth resistor and a tenth resistor; the second branch includes a second transistor; and the third branch includes a third transistor and an eleventh resistor; and the second transistor and the third transistor are of a same type; and
where one terminal of the ninth resistor, a first electrode of the second transistor, and a first electrode of the third transistor are all connected to the power supply; another terminal of the ninth resistor is connected to one terminal of the tenth resistor and a control electrode of the second transistor; another terminal of the tenth resistor, a second electrode of the second transistor, and a second electrode of the third transistor are all grounded; a control electrode of the third transistor is connected to the first electrode of the second transistor; the first electrode of the third transistor is further connected to the enable terminal of the audio amplifier; one terminal of the eleventh resistor is connected to the first electrode of the third transistor; and another terminal of the eleventh resistor is connected to the second electrode of the third transistor.

In some embodiments, the second branch further includes a twelfth resistor; and the third branch further includes a thirteenth resistor; and
where the twelfth resistor is connected in series between the power supply and the first electrode of the second transistor, and the thirteenth resistor is connected in series between the power supply and the first electrode of the third transistor.

In some embodiments, the first branch includes a fourteenth resistor; the second branch includes a first diode, a fourth transistor, and a fifteenth resistor; and the third branch includes a sixteenth resistor, a fifth transistor, a fourth capacitor, and a second diode, and the fourth transistor and the fifth transistor are of different types; and
where one terminal of the fourteenth resistor and an input terminal of the first diode are both connected to the power supply; another terminal of the fourteenth resistor is connected to a control electrode of the fourth transistor; a first electrode of the fourth transistor is connected to an output terminal of the first diode, one terminal of the fourth capacitor, and one terminal of the sixteenth resistor; a second electrode of the fourth transistor is connected to a control electrode of the fifth transistor and one terminal of the fifteenth resistor; another terminal of the fifteenth resistor, a second electrode of the fifth transistor, an input terminal of the second diode, and another terminal of the fourth capacitor are all grounded; and a first electrode of the fifth transistor is connected to another terminal of the sixteenth resistor, an output terminal of the second diode, and the enable terminal of the audio amplifier.

In some embodiments, the power supply circuit includes a buck DC-DC converter, and the buck DC-DC converter includes a driver chip, a first switch, a second switch, an output inductor, and an output capacitor; and
where a feedback terminal of the driver chip, as a feedback terminal of the power supply circuit, is connected to the feedback control circuit; an input terminal of the driver chip, as the input terminal of the power supply circuit, is connected to the feedback control circuit; a first output terminal of the driver chip is connected to a control terminal of the first switch; a second output terminal of the driver chip is connected to a control terminal of the second switch; an input terminal of the first switch is connected to a power supply; an input terminal of the second switch is grounded; an output terminal of the first switch and an output terminal of the second switch are both connected to a first terminal of the output inductor; a second terminal of the output inductor, as the output terminal of the power supply circuit, is connected to the power terminal of the audio amplifier; and the output capacitor is connected in series between the input terminal of the second switch and the second terminal of the output inductor.

In some embodiments, the driver chip includes a second operational amplifier, a comparator, a driver, and an inverter that are successively connected.

In some embodiments, the audio processing circuit further includes a filter circuit, connected between the input terminal of the audio amplifier and the feedback control circuit; and
where the filter circuit is configured to filter the audio signal, and transmit a filtered audio signal to the feedback control circuit.

In some embodiments, the filter circuit includes a second-order Butterworth low-pass filter.

In some embodiments, the audio amplifier is a digital amplifier chip including a switch amplifier.

In some embodiments, the controller includes a microcontroller unit.

In another aspect of the embodiments of the present disclosure, an audio playback module is provided. The audio playback module includes an audio playback assembly, and the audio processing circuit as described in the above aspect;
where the audio processing circuit is connected to the audio playback assembly, and is configured to drive the audio playback assembly to play audio.

In another aspect of the embodiments of the present disclosure, an electronic device is provided. The electronic device includes a device body, and the audio playback module that is arranged in the device body as described in the above aspect.

### BRIEF DESCRIPTION OF DRAWINGS

For clearer descriptions of the technical solutions according to the embodiments of the present disclosure, drawings that are to be referred for description of the embodiments are briefly described hereinafter. Apparently, the drawings described hereinafter merely illustrate some embodiments of the present disclosure. Persons of ordinary skill in the art may also derive other drawings based on the drawings described herein without any creative effort.

FIG. 1 is an architecture diagram of an implementation environment of an audio processing circuit according to some embodiments of the present disclosure;

FIG. 2 is a schematic structural diagram of an audio processing circuit according to some embodiments of the present disclosure;

FIG. 3 is a schematic structural diagram of an audio processing circuit according to some embodiments of the present disclosure;

FIG. 4 is a schematic structural diagram of an audio processing circuit according to some embodiments of the present disclosure;

FIG. 5 is a schematic structural diagram of an audio processing circuit according to some embodiments of the present disclosure;

FIG. 6 is a schematic circuit structural diagram of a feedback control circuit according to some embodiments of the present disclosure;

FIG. 7 is a schematic structural diagram of an audio processing circuit according to some embodiments of the present disclosure;

FIG. 8 is a schematic circuit structural diagram of a power-on protection circuit according to some embodiments of the present disclosure;

FIG. 9 is a schematic circuit structural diagram of a power-on protection circuit according to some embodiments of the present disclosure;

FIG. 10 is a waveform of an output signal of a power-on protection circuit according to some embodiments of the present disclosure;

FIG. 11 is a schematic structural diagram of an audio processing circuit according to some embodiments of the present disclosure;

FIG. 12 is a schematic structural diagram of a brown-out protection circuit according to some embodiments of the present disclosure;

FIG. 13 is a schematic circuit structural diagram of a brown-out protection circuit according to some embodiments of the present disclosure;

FIG. 14 is a schematic circuit structural diagram of a brown-out protection circuit according to some embodiments of the present disclosure;

FIG. 15 is a schematic circuit structural diagram of a brown-out protection circuit according to some embodiments of the present disclosure;

FIG. 16 is a schematic circuit structural diagram of a power supply circuit according to some embodiments of the present disclosure;

FIG. 17 is a schematic structural diagram of an audio processing circuit according to some embodiments of the present disclosure;

FIG. 18 is a schematic circuit structural diagram of a filter circuit according to some embodiments of the present disclosure;

FIG. 19 is a schematic circuit structural diagram of an audio processing circuit according to some embodiments of the present disclosure;

FIG. 20 is a schematic structural diagram of an audio playback module according to some embodiments of the present disclosure; and

FIG. 21 is a schematic structural diagram of an electronic device according to some embodiments of the present disclosure.

### DETAILED DESCRIPTION

For clearer descriptions of the objectives, technical solutions, and advantages of the present disclosure, embodiments of the present disclosure are described hereinafter in detail with reference to the accompanying drawings. It should be understood that the embodiments described herein are only some exemplary ones for illustrating the present disclosure, and are not intended to limit the present disclosure. It should be additionally noted that for ease of description, portions that are relevant to the present invention are merely illustrated.

It should be noted that in cases of no conflict, the embodiments and features in the embodiments of the present invention may be combined together. The present disclosure is described hereinafter in detail with reference to the accompanying drawings and specific embodiments.

With the expansion of the IoT and smart home markets, electronic products such as refrigerators, washing machines, robotic vacuums, cooking machines, and air purifiers have incorporated display modules to enable human-computer interaction, making applications that enhance the technological feel of products more widespread. An example of a display module is an LCD module. However, with continuous technological advancements, traditional display modules no longer meet market demands. As seen from the implementation environment architecture illustrated in FIG. 1, a new system board 10 has emerged, which is integrated into a traditional display module. The system board 10 may include components such as a microcontroller unit (MCU)/system on chip (SoC), wireless fidelity (Wi-Fi), a speaker, and a microphone, which are integrated into the LCD module to form an LCD enhanced module. In other words, the system board 10 integrates images, audio, and video, such that the LCD enhanced module has audio and video playback capabilities to implement functions such as video playback and voice guidance, which further enhances human-computer interaction. The system board 10 offers advantages such as integration, localized image resources, and simplified user interfaces, and also increases the value of the display module. Due to the small size, high efficiency, and low cost of class D audio power amplifiers, the system board 10 in the LCD enhanced module typically uses a class D audio power amplifier for audio playback. In other words, a common low-cost audio playback implementation is to use an audio playback module that includes a class D audio power amplifier. However, during use, the following issues have been observed:

In one aspect, the power supply circuit is usually externally connected to a power supply, and provides a supply voltage to the class D audio power amplifier based on a power signal provided by the power supply. In other words, the class D audio power amplifier does not have an independent regulatable power supply. Therefore, in the case that an output power of the class D audio power amplifier fluctuates, the power supply may become unstable, causing the speaker to produce a “howling” noise. Specifically, when the amplitude of the audio signal transmitted to the class D audio power amplifier changes significantly, the output power of the amplifier also increases, resulting in the speaker producing a louder sound. Moreover, fluctuations in output power may cause the voltage of the power signal to fluctuate as well. In the case that the output power suddenly increases, due to the hysteresis of the feedback loop, the power supply circuit fails to regulate the voltage in time, and consequently a supply voltage suddenly decreases, which leads to a decrease in the output power of the class D audio power amplifier and causes the speaker to produce a lower sound volume. The supply voltage may also suddenly rise accordingly. Although the supply voltage may gradually stabilize to its normal state, the instantaneous instability of the supply voltage causes sound distortion and leads to the “howling” noise described in the background.

Additionally, since the power supply circuit typically powers both the class D audio power amplifier and the controller that transmits the audio signal to the class D audio power amplifier, this results in the class D audio power amplifier being affected by ground potential fluctuations at the instant of power-up and power-down. This can cause the amplifier to drive the speaker to produce a “popping” noise, which generates noise within the audible frequency range, and is unpleasant to the human ear. Typically, such transient shocks are narrow pulses, and when analyzed via Fourier transform, their frequency spectrum contains a rich set of components with a relatively even energy distribution across the frequency domain. The objective is to reduce harmonic components within the range of 20 Hz to 20 kHz, as the majority of human ears cannot hear sound if the peak voltage is less than 10 millivolts (mV).

In other words, when the amplitude of the audio signal input to the system board 10 in the LCD enhanced module changes significantly, the output power of the class D audio power amplifier also varies, which in turn causes fluctuations in the power supply to the system board 10. Due to the lack of an independently regulatable power supply for the class D audio power amplifier, in the case that the output power of the class D audio power amplifier changes, the hysteresis of the power supply loop prevents the voltage from being regulated in time by the buck converter circuit. This results in a sudden increase or decrease in the supply voltage to the class D audio power amplifier, causing sound distortion or even howling. Therefore, the sound played by the class D audio power amplifier suffers from a poor sound quality, such as anomalies like “howling” and “popping” noises.

It should be noted that the above explanation uses the class D audio power amplifier as an example. In some other embodiments, power amplifiers of other types (e.g., class A) may also experience the same issues.

Based on this, some embodiments of the present disclosure provide an audio processing circuit that matches the amplitude of the audio signal with the voltage of the audio power amplifier, such that the howling problem is resolved, the sound quality of the playback is optimized, and anomalies such as “howling” and “popping” noises are prevented. This ensures that the audio playback effect is improved.

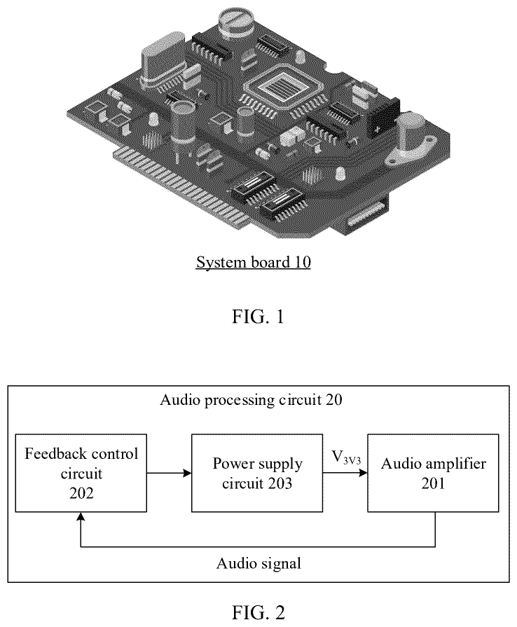

FIG. 2 is a schematic structural diagram of an audio processing circuit according to some embodiments of the present disclosure. This circuit may be applied to the system board as described above to implement audio amplification, which may also be referred to as an audio amplification circuit. As illustrated in FIG. 2, the audio processing circuit 20 includes an audio amplifier 201, a feedback control circuit 202, and a power supply circuit 203.

The feedback control circuit 202 is connected to an input terminal of the audio amplifier 201 and an input terminal of the power supply circuit 203, and an output terminal of the power supply circuit 203 is connected to a power terminal of the audio amplifier 201. That is, the power supply circuit 203 is capable of being connected to the input terminal of the audio amplifier 201 via the feedback control circuit 202.

Optionally, the audio amplifier 201 may include a class D audio power amplifier as described above, which is also referred to as an audio power amplifier module. The feedback control circuit 202 may be a feedback control circuit used by a power supply to stabilize an output voltage, and may also be referred to as a feedback module. The power supply circuit 203 may be configured to output a constant direct current (DC) voltage. Exemplarily, the power supply circuit 203 may be a DC-DC converter. In addition, the power supply circuit 203 may be a buck converter circuit in a DC-DC power supply, such that changes of the circuit are quickly responded. For example, the buck converter circuit may reduce a received 5 V voltage to a 3.3 V voltage for output. Based on this, in FIG. 2, the output terminal of the power supply circuit 203 is marked by V_{3V3}. Nevertheless, the power supply circuit 203 may also be a boost DC-DC converter.

The feedback control circuit 202 is configured to control, based on an audio signal received at the input terminal of the audio amplifier 201, the power supply circuit 203 to regulate a supply voltage provided to the power terminal of the audio amplifier 201, wherein a magnitude of the supply voltage upon regulation is positively correlated with an amplitude of the audio signal. Correspondingly, the power supply circuit 203 may also be referred to as a voltage regulation module. The audio signal may be sine may be a continuous sinusoidal analog voltage signal, and used for representing variations in the frequency and amplitude of sound waves.

In the embodiment of the present disclosure, when the amplitude of the audio signal input to the audio amplifier 201 changes, a feedback control circuit 202 is added between the input terminal of the audio amplifier 201 and the power supply circuit 203. The controller 204 transmits the audio signal from the audio amplifier 201 to the feedback control circuit 202, and the feedback control circuit 202 determines a supply voltage for the audio amplifier 201 suitable for the current audio signal based on the current audio signal, such that the amplitude of the audio signal is matched with the voltage of the audio amplifier 201.

In addition, in the case that the amplitude of the audio signal suddenly increases, the feedback control circuit 202 may regulate the supply voltage provided by the power supply circuit 203 to the audio amplifier 201 to respond to the sudden increase in the output power of the audio amplifier 201; or in the case that the amplitude of the audio signal suddenly decreases, the feedback control circuit 202 may regulate the supply voltage provided by the power supply circuit 203 to the audio amplifier 201 to respond to the sudden decrease in the output power of the audio amplifier 201. That is, for the power supply circuit 203, it is possible to predict the upcoming changes in the audio amplifier 201 and respond to these changes in advance. In this way, the supply voltage provided by the power supply circuit 203 may be reliably kept as stable as possible, such that instantaneous instability is avoided and thereby the “howling” noise is prevented. This achieves the objective of optimizing sound quality and ensuring a better audio playback effect.

In summary, the embodiments of the present disclosure provide an audio processing circuit. The audio processing circuit adds a feedback control circuit between the power supply circuit and the audio amplifier, such that the feedback control circuit is allowed to control the regulation of the supply voltage provided to the audio amplifier based on changes of the amplitude of the audio signal received by the audio amplifier. In this way, in the case that the amplitude of the audio signal changes, the feedback control circuit is capable of figuring out the appropriate supply voltage matched with the audio amplifier for the audio amplifier, such that the problem of howling that occurs in response to the changes of the amplitude of the audio signal in the audio playback module is resolved, and the sound quality during playback is optimized.

Optionally, in the embodiments of the present disclosure, the feedback control circuit 202 may be configured to regulate an input voltage at the input terminal of the power supply circuit 203 based on the audio signal, wherein a magnitude of the input voltage upon regulation is negatively correlated with the amplitude of the audio signal. That is, the larger the amplitude of the audio signal, the smaller the regulated input voltage; the smaller the amplitude of the audio signal, the larger the regulated input voltage.

The power supply circuit 203 may be configured to regulate, based on the input voltage upon regulation, the supply voltage provided to the power terminal of the audio amplifier 201.

That is, the feedback control circuit 202 may regulate a voltage at a connection terminal between the feedback control circuit 202 and the power supply circuit 203 based on the changes of the amplitude of the audio signal input to the audio amplifier 201, such that the power supply circuit 203 is capable of regulating the supply voltage provided to the power terminal of the audio amplifier 201. The voltage at the connection terminal is also referred to as a target voltage.

Optionally, in some embodiments, the feedback control circuit 202 may transmit a control signal based on the audio signal to the input terminal of the power supply circuit 203 to regulate the supply voltage output from the output terminal of the power supply circuit 203. Correspondingly, the input terminal of the power supply circuit 203 may also be referred to as a control terminal.

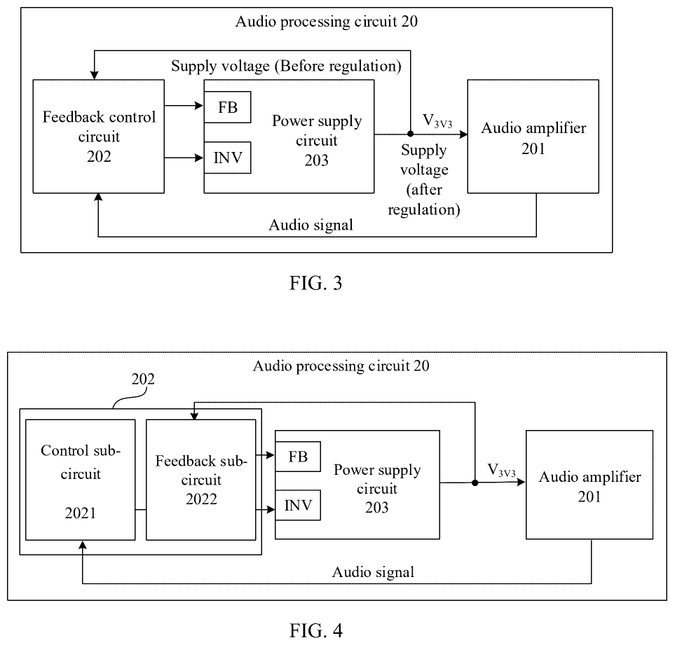

Optionally, FIG. 3 is a schematic structural diagram of a drive circuit according to some embodiments of the present disclosure. As illustrated in FIG. 3, the feedback control circuit 202 may be further connected to both the output terminal and the feedback terminal of the power supply circuit 203, and may be further configured to feed back the supply voltage provided by the power supply circuit 203 to the power terminal of the audio amplifier 201 to the feedback terminal of the power supply circuit 203.

For differentiation, in FIG. 3, the feedback terminal of the power supply circuit 203 is marked as FB, and the input terminal of the power supply circuit 203 is marked as INV.

It may be understood that, in conjunction with FIG. 3, the supply voltage fed back by the feedback control circuit 202 to the feedback terminal FB of the power supply circuit 203 may be the supply voltage before regulation. Additionally, under the control of the feedback control circuit 202, the power supply circuit 203 may regulate the supply voltage based on the amplitude of the audio signal, and then transmits the regulated supply voltage to the audio amplifier 201, to ensure that the audio amplifier 201 is capable of reliably driving a connected audio playback assembly to play audio.

Optionally, FIG. 4 is a schematic structural diagram of an audio processing circuit according to some embodiments of the present disclosure. As illustrated in FIG. 4, the feedback control circuit 202 may include a control sub-circuit 2021 and a feedback sub-circuit 2022.

The control sub-circuit 2021 may be connected to the input terminal INV of the power supply circuit 203 via the feedback sub-circuit 2022, and the control sub-circuit 2021 may be further connected to the input terminal of the audio amplifier 201. The feedback sub-circuit 2022 may be further connected to both the output terminal and the feedback terminal FB of the power supply circuit 203.

The control sub-circuit 2021 may be configured to regulate an input voltage at the input terminal INV of the power supply circuit 203 based on the audio signal. For example, as described above, the control sub-circuit 2021 may transmit the control signal to the input terminal INV of the power supply circuit 203, to control the power supply circuit 203 to regulate the supply voltage, such that the audio playback effect is optimized. Correspondingly, the control sub-circuit 2021 may also be referred to a howling optimization circuit.

The feedback sub-circuit 2022 may be configured to feed back the supply voltage provided by the power supply circuit 203 to the power terminal of the audio amplifier 201 to the feedback terminal of the power supply circuit 203. That is, the supply voltage before regulation may be fed back to the feedback terminal FB of the power supply circuit 203 via the feedback sub-circuit 2022. Correspondingly, the feedback sub-circuit 2022 may also be referred to as a feedback control section.

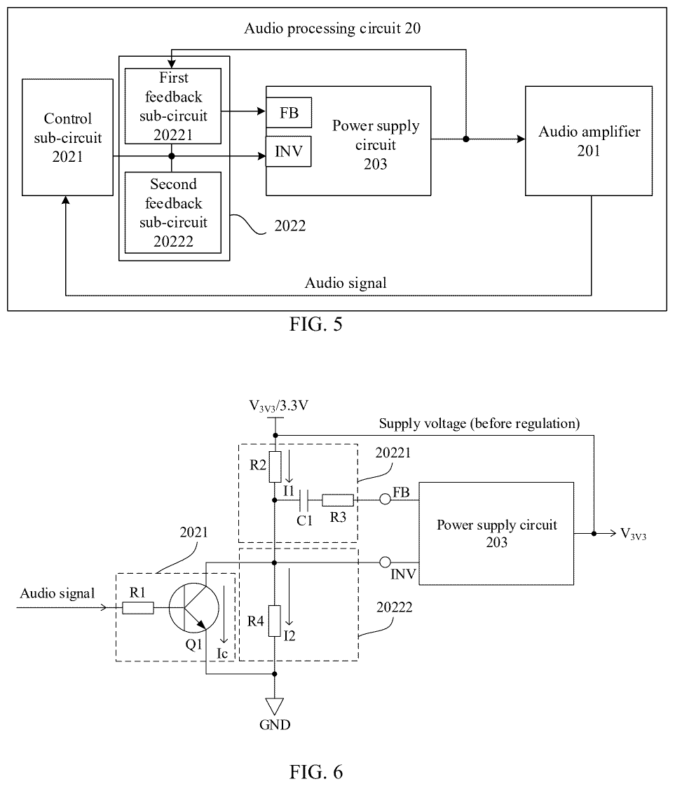

Optionally, FIG. 5 is a schematic structural diagram of an audio processing circuit according to some embodiments of the present disclosure. As illustrated in FIG. 5, the feedback sub-circuit 2022 may include a first feedback sub-circuit 20221 and a second feedback sub-circuit 20222.

A first terminal of the first feedback sub-circuit 20221 may be connected to the output terminal of the power supply circuit 203, a second terminal of the first feedback sub-circuit 20221 may be connected to the feedback terminal FB of the power supply circuit 203, and a third terminal of the first feedback sub-circuit 20221 may be connected to the control sub-circuit 2021, the second feedback sub-circuit 20222, and the input terminal INV of the power supply circuit 203.

That is, in the embodiments of the present disclosure, the feedback control circuit 202 may be divided into three sub-modules: the control sub-circuit 2021, the first feedback sub-circuit 20221, and the second feedback sub-circuit 20222. An input terminal of the first feedback sub-circuit 20221 may be connected to the power terminal of the audio amplifier 201, and an output terminal of the first feedback sub-circuit 20221 may be connected to the control sub-circuit 2021 and the second feedback sub-circuit 20222. The control sub-circuit 2021 may be connected to the input terminal of the audio amplifier 201, and a current of the control sub-circuit 2021 changes with changes of the amplitude of the audio signal. The second feedback sub-circuit 20222 may be connected to the power supply circuit 203, and in the case that a current of the second feedback sub-circuit 20222 changes, a voltage at a connection terminal between the second feedback sub-circuit 20222 and the power supply circuit 203 is the target voltage.

A magnitude of the current of the control sub-circuit 2021 may be positively correlated with a magnitude of the amplitude of the audio signal. That is, the larger the amplitude of the audio signal, the larger the current of the control sub-circuit 2021; and the smaller the amplitude of the audio signal, the smaller the current of the control sub-circuit 2021. A magnitude of the current of the second feedback sub-circuit 20222 may be negatively correlated with the magnitude of the current of the control sub-circuit 2021. That is, the larger the current of the control sub-circuit 2021, the smaller the current of the second feedback sub-circuit 20222; and the smaller the current of the control sub-circuit 2021, the larger the current of the second feedback sub-circuit 20222. The input voltage at the input terminal INV of the power supply circuit 203 may be positively correlated with the magnitude of the current of the second feedback sub-circuit 20222. That is, the larger the current of the second feedback sub-circuit 20222, the larger the input voltage at the input terminal INV of the power supply circuit 203; and the smaller the current of the second feedback sub-circuit 20222, the smaller the input voltage at the input terminal INV of the power supply circuit 203. In this way, the voltage at the input terminal INV of the power supply circuit 203 is regulated based on the amplitude of the audio signal.

That is, in the embodiments of the present disclosure, the changes of the amplitude of the audio signal may cause changes of the currents of various sub-modules in the feedback control circuit 202, such that an appropriate supply voltage for the audio amplifier 201 is determined based on the changes of the currents of the various sub-modules.

In addition, in a possible implementation, the power terminal of the audio amplifier 201 connected to the input terminal of the first feedback sub-circuit 20221 may be an input terminal of an original supply voltage of the audio amplifier 201, that is, the supply voltage before regulation as described above. The original supply voltage of the audio amplifier 201 may be provided by the power supply circuit 203, for example, the 3.3 V voltage as described above.

In another possible implementation, after the original supply voltage of the audio amplifier 201 is input into the first feedback sub-circuit 20221, the current of the first feedback sub-circuit 20221 may flow toward the control sub-circuit 2021 and the second feedback sub-circuit 20222.

In another possible implementation, the input terminal of the audio amplifier 201 connected to the control sub-circuit 2021 is an input terminal of the audio signal. Therefore, the control sub-circuit 2021 may receive the audio signal. Exemplarily, in the case that the amplitude of the audio signal changes, the voltage desired by the audio signal also changes. In this way, the current of the control sub-circuit 2021 may change with the changes of the voltage of the audio signal.

In another possible implementation, the voltage at the connection terminal between the second feedback sub-circuit 20222 and the power supply circuit 203 is the target voltage as described above.

Exemplarily, as described above, in the case that the original supply voltage input into the first feedback sub-circuit 20221 does not change, a total current flowing from the first feedback sub-circuit 20221 toward the control sub-circuit 2021 and the second feedback sub-circuit 20222 does not change. Therefore, in the case that the current of the control sub-circuit 2021 changes with the changes of the amplitude of the audio signal, the current flowing toward the second feedback sub-circuit 20222 changes, and hence the target voltage at the connection terminal between the second feedback sub-circuit 20222 and the power supply circuit 203 changes.

For example, in the case that the amplitude of the audio signal becomes larger, the current of the control sub-circuit 2021 becomes larger accordingly, the current flowing toward the second feedback sub-circuit 20222 decreases accordingly, and the target voltage decreases with the decrease of the current of the second feedback sub-circuit 20222; or in the case that the amplitude of the audio signal becomes smaller, the current of the control sub-circuit 2021 becomes smaller accordingly, the current flowing toward the second feedback sub-circuit 20222 increases accordingly, and the target voltage increases with the increase of the current of the second feedback sub-circuit 20222. Therefore, the amplitude of the audio signal is negatively correlated with the target voltage as described above.

Optionally, FIG. 6 is a schematic structural diagram of an audio processing circuit according to some embodiments of the present disclosure. As illustrated in FIG. 6, the control sub-circuit 2021 may include a first resistor R1 and a first transistor Q1.

One terminal of the first resistor R1 may be connected to the input terminal (not illustrated) of the audio amplifier 201, another terminal of the first resistor R1 may be connected to a control electrode (also referred to as a first terminal) of the first transistor Q1, a first electrode (also referred to as a second terminal) of the first transistor Q1 may be connected to the input terminal INV of the power supply circuit 203 via the feedback sub-circuit 2022, and a second electrode (also referred to as a third terminal) of the first transistor Q1 may be grounded, that is, connected to ground GND.

Optionally, still referring to FIG. 6, the first feedback sub-circuit 20221 may include a second resistor R2, a third resistor R3, and a first capacitor C1. The second feedback sub-circuit 20222 may include a fourth resistor R4.

One terminal of the second resistor R2 may be connected to the output terminal of the power supply circuit 203; another terminal of the second resistor R2 is connected to one terminal of the first capacitor C1, one terminal of the fourth resistor R4, the control sub-circuit 2021, and the input terminal INV of the power supply circuit 203; another terminal of the first capacitor C1 may be connected to one terminal of the third resistor R3; another terminal of the third resistor R3 may be connected to the feedback terminal FB of the power supply circuit 203; and another terminal of the fourth resistor R4 may be grounded.

It may be understood that with reference to FIG. 6 and the above disclosure, in the case that the amplitude of the audio signal changes, a voltage across the two terminals of the first resistor R1 changes accordingly, such that a current flowing from the first electrode of the first transistor Q1 toward the second electrode of the first transistor Q1 changes. For example, in the case that the amplitude of the audio signal becomes larger, the voltage across the two terminals of the first resistor R1 increases, such that the current flowing from the first electrode of the first transistor Q1 toward the second electrode of the first transistor Q1 increases.

Optionally, the first transistor Q1 may be an NPN-type triode as illustrated in FIG. 6. Correspondingly, the control electrode (that is, the first terminal) of the first transistor Q1 may refer to a base electrode of the NPN-type triode, the first electrode (that is, the second terminal) of the first transistor Q1 may refer to a collector electrode of the NPN-type triode, and the second electrode (that is, the third terminal) of the first transistor Q1 may refer to an emitter electrode of the NPN-type triode. Hereinafter, transistors of the triode type are named likewise, which is not described herein any further.

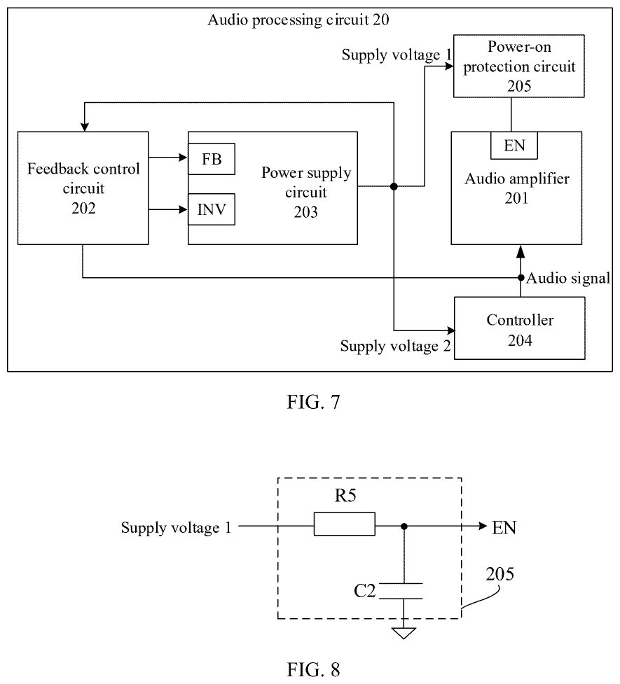

Optionally, based on FIG. 3, FIG. 7 is a schematic structural diagram of an audio processing circuit according to some embodiments of the present disclosure. As illustrated in FIG. 7, the audio processing circuit may further include a controller 204. An output terminal of the controller 204 is connected to the input terminal of the audio amplifier 201, and the output terminal of the power supply circuit 203 may be further connected to a power terminal of the controller 204.

The power supply circuit 203 may be further configured to provide the supply voltage to the power terminal of the controller 204. That is, the power supply circuit 203 may further supply power to the controller 204.

The controller 204 may be further configured to generate the audio signal as described above based on a stored digital signal, and output the generated audio signal to the input terminal of the audio amplifier 201 in the case of power-on. That is, the controller 204 is capable of generating the audio signal under drive of the supply voltage provided by the power supply circuit 203, and outputting the audio signal to the audio amplifier 201.

Optionally, the digital signal in the controller 204 may be an audio file to be played back by the audio amplifier 201. The audio file may be a programming code file. Specifically, the controller 204 may generate the audio signal from the digital signal in the audio file by decoding and analog-to-digital conversion. Correspondingly, the controller 204 may also be referred to as a signal processing module.

Optionally, the controller 204 may be a chip-level computer formed by appropriately reducing the frequency and specifications of a central processing unit (CPU) and integrating a peripheral interface such as memory, counter, USB, A/D conversion, UART, PLC, DMA, and an LCD driver circuit onto a single chip. For example, the controller may be an MCU, or may be an SoC.

The audio amplifier 201 may be configured to drive, based on the audio signal, a connected audio playback assembly to play audio in the case of power-on. The audio playback assembly may be, for example, a speaker. That is, in the embodiments of the present disclosure, in the case that the audio amplifier 201 is powered on, the controller 204 may generate the audio signal from the digital signal, and inputs the audio signal into the audio amplifier 201 for playback. Exemplarily, currents of various branches in the audio amplifier 201 are conducted by turning on the power supply (for example, the supply voltage as described above) at the input terminal of the audio amplifier 201, such that the audio amplifier 201 is in a powered-on state.

It may be understood that as illustrated in FIG. 7, the power supply circuit 203 provides a supply voltage 1 to the audio amplifier 201, and the power supply circuit 203 provides a supply voltage 2 to the controller 204. The power supply circuit 203 regulates the supply voltage 1.

Currently, the power supply circuit 203 may simultaneously supply power to the audio amplifier 201 and the controller 204. Therefore, at the instant the audio amplifier 201 is powered on, the audio signal generated by the controller 204 is not received, and consequently the ground potential is subjected to transient fluctuations, which subsequently causes a popping noise during audio playback. It should be noted that the popping noise caused by transient fluctuations is a sharp pulse signal, which contains numerous high-order harmonics. Therefore, by reducing the peak-to-peak voltage of the sharp pulse signal, the high-order harmonics within a preset range may be minimized, such that the problem of the popping noise is resolved.

In the embodiments of the present disclosure, still referring to FIG. 7, the audio processing circuit 20 may further include a power-on protection circuit 205 connected between the output terminal of the power supply circuit 203 and the audio amplifier 201.

The power-on protection circuit 205 may be configured to control the audio amplifier 201 to be powered on in the case that the controller 204 is powered on, such that power-on of the controller 204 is earlier than that of the audio amplifier 201. It may be understood that the power-on protection circuit 205 extends the time for the audio amplifier 201 to reach the normal supply voltage, such that the supply voltage of the controller 204 is nearly stabilized before the audio amplifier 201 is powered on. In this way, the problem of the popping noise during power-on of the audio amplifier module 202 at present is resolved. Correspondingly, the power-on protection circuit 205 may also be referred to as a delay module.

Exemplarily, still referring to FIG. 7, in the embodiments of the present disclosure, the power-on protection circuit 205 may be connected to the enable terminal EN (also referred to as an enable pin) of the audio amplifier 201. The power-on protection circuit 205 may be configured to perform voltage division on the supply voltage provided by the power supply circuit 203 to the power terminal of the audio amplifier 201, and output a divided voltage to the enable terminal of the audio amplifier 201 to power on the audio amplifier 201.

The audio amplifier 201 may be configured to drive, based on the audio signal, the audio playback assembly to play back the audio in the case that a voltage at the enable terminal EN of the audio amplifier 201 is greater than an enable voltage threshold; A duration for which the voltage at the enable terminal is greater than the enable voltage threshold is greater than or equal to a duration required for the controller 204 to enter a stable operating state.

An input terminal of the power-on protection circuit 205 may be connected to the output terminal of the power supply circuit 203, and an output terminal of the power-on protection circuit 205 may be connected to the enable terminal EN of the audio amplifier 201. The power-on protection circuit 205 may be configured to transmit an enable signal with a voltage greater than the enable voltage threshold to the enable terminal EN of the audio amplifier 201 in the case that the power supply circuit 203 has provided the supply voltage for a target duration. As described above, the target duration may be greater than or equal to the time required for the controller 204 to reach a stable operating state in the case that the power supply circuit 203 provides the supply voltage to the controller 204. In other words, the time required to reach the enable threshold voltage for the enable pin of the audio amplifier 201 to become effective may correspond to the time required for the controller 204 to achieve a stable state. This ensures that before the audio amplifier 201 begins operation, the controller 204 already provides a stable output audio signal.

Thus, it may also be understood that the audio amplifier 201 may be configured to drive the audio playback assembly to play audio, i.e., to start operating, based on the audio signal under the control of the enable signal received at the enable terminal EN; and may be configured to stop driving the audio playback assembly to play audio, i.e., to stop operating, under the control of a disable signal received at the enable terminal EN (i.e., in the case that the voltage at the enable terminal EN is less than the enable voltage threshold). In other words, the enable signal may refer to an activation signal that allows the audio amplifier 201 to start functioning. Accordingly, the enable pin of the audio amplifier 201 may also refer to a high-level enable (EN) pin.

Optionally, in some embodiments, the enable voltage threshold may be predetermined. For example, some specifications of the audio amplifier 201 indicate that in scenarios where the input voltage received by the power supply circuit 203 is 5V, the enable voltage threshold may be 1.2 V. Thus, it may be understood that in the case that the voltage at the enable terminal EN exceeds 1.2 V, the audio amplifier 201 starts operating.

That is, in the embodiments of the present disclosure, the power supply circuit 203 may not simultaneously provide a supply voltage to both the controller 204 and the audio amplifier 201 to trigger both the controller 204 and the audio amplifier 201 to enter their operating states simultaneously. Instead, the power supply circuit 203 is controlled to first provide a supply voltage to the controller 204 to trigger the controller 204 to enter its operating state, generate an audio signal, and transmit the audio signal. Then, in the case that the controller 204 reaches a stable operating state, upon elapse of a target duration, the power supply circuit 203 is controlled to provide a supply voltage to the audio amplifier 201 to trigger the audio amplifier 201 to enter its operating state. In other words, the power-on protection circuit 205 may delay the provision of the supply voltage by a target duration before transmitting the supply voltage to the audio amplifier 201, thereby triggering a delayed start of the audio amplifier 201. In this way, the audio amplifier 201 may be powered on after the controller 204, allowing the controller 204 to stabilize before the audio amplifier 201 is powered on. Hence, the operating stability of the audio amplifier 201 is ensured, and the audio amplifier 201 is prevented from producing sound before the controller 204 is stabilized and starts outputting the audio signal. This further helps avoid the “popping” noise during audio playback described in the above embodiments, thereby optimizing audio quality.

Optionally, as an alternative implementation, as illustrated in FIG. 8, the power-on protection circuit 205 may include a passive integrator. The passive integrator may include a fifth resistor R5 and a second capacitor C2, which is also referred to as an RC circuit.

One terminal of the fifth resistor R5 may be connected to the output terminal (not illustrated) of the power supply circuit 203 to receive the supply voltage provided by the power supply circuit 203 (herein referred to as a supply voltage 1). another terminal of the fifth resistor R5 may be connected to one terminal of the second capacitor C2 and the enable terminal EN of the audio amplifier 201, and another terminal of the second capacitor C2 may be grounded.

Optionally, the resistance and capacitance of the resistor and capacitor in the power-on protection circuit 205 may be determined by performing a time-domain analysis on an output of the RC circuit. For example, based on FIG. 8, designing of parameters of the power-on protection circuit 205 is described as follows:
1. Based on the RC output time-domain function, the following may be determined:

$${V}_{E} = {V}_{3 V 30} - r 50 c 20 \frac{{dV}_{E}}{dt} ;$$

2. The RC output time-domain function may be simplified into a first-order linear non-homogeneous differential equation:

$${V}_{E} = {V}_{3 V 30} - r 50 c 20 {V}_{E}^{′} ;$$

3. The differential equation is solved, a general solution of the differential equation is

$${Ce}^{- \int \frac{1}{r 50 c 20} dt} ;$$

a particular solution of the differential equation is

$${Ce}^{- \int \frac{1}{r 50 c 20} dt} \int \frac{U}{r 50 c 20} {e}^{\int \frac{1}{r 50 c 20} dt} ;$$

and hence

$${V}_{E} = {V}_{3 V 30} + {Ae}^{- \frac{t}{r 50 c 20}} ;$$

is derived.
4. When t=0, V_{E}=0, and the constant A=−V_{3V30} may be introduced to obtain

$${V}_{E} = {V}_{3 V 30} - {V}_{3 V 30} {e}^{- \frac{t}{r 50 c 20}} .$$

The following is obtained by taking the logarithm of both sides of the equation:

$$r 50 c 20 = \frac{- t}{ln ( \frac{{V}_{3 V 30} - {V}_{E}}{{V}_{3 V 30}} )} \qquad Formula ( 1 )$$

r50 may refer to the resistance of the fifth resistor R5, c20 may refer to the capacitance of the second capacitor C2, V_{E}may refer to the voltage at the enable terminal EN, V_{3V30} may refer to the supply voltage, and t may refer to the duration reserved for the controller 204 to enter the stable operating state, that is, the target duration as described above.

For example, assuming that V_{E}=1.2 V, V_{3V30}=3.3 V, and t=100 milliseconds (ms), then by substituting into Formula (1), it can be calculated that: r50c20=0.22. The capacitance c20 of the second capacitor C2 may be selected as the commonly used value of 100 nanofarads (nF), and accordingly, the resistance of the fifth resistor R5 may be determined as r50=0.22/(1*10⁻⁵)=22 Kohms (kQ).

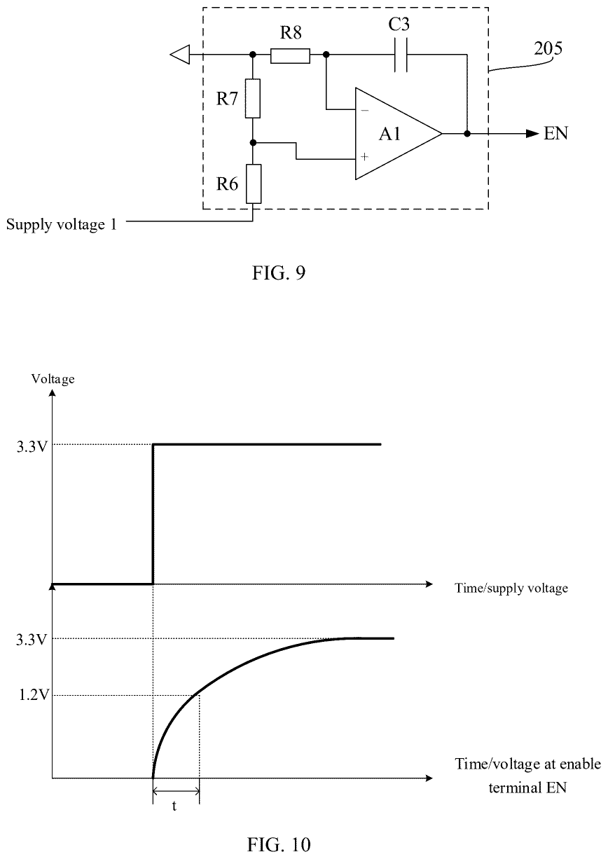

As another alternative implementation, as illustrated in FIG. 9, the power-up protection circuit 205 may include an active integrator. The active integrator includes a sixth resistor R6, a seventh resistor R7, an eighth resistor R8, a third capacitor C3, and a first operational amplifier (AMP) A1.

One terminal of the sixth resistor R6 may be connected to the output terminal (not illustrated) of the power supply circuit 203 to receive the supply voltage provided by the power supply circuit 203 (herein referred to as a supply voltage 1). Another terminal of the sixth resistor R6 may be connected to one terminal of the seventh resistor R7 and a non-inverting input terminal (+) of the first operational amplifier A1, another terminal of the seventh resistor R7 may be connected to one terminal of the eighth resistor R8 and is grounded, another terminal of the eighth resistor R8 may be connected to an inverting input terminal (−) of the first operational amplifier A1 and one terminal of the third capacitor C3, another terminal of the third capacitor C3 may be connected to an output terminal of the first operational amplifier A1, and the output terminal of the first operational amplifier A1 may be further connected to an enable terminal EN of the power supply circuit 201.

Optionally, based on FIG. 9, designing of parameters for the active integrator is described hereinafter.

The input and output voltages of the active integrator in FIG. 9 satisfy Formulas (2) and (3):

$$Vo = {V}_{+} \times \frac{t}{r 80 \times c 30} + {V}_{+} ; \qquad Formula ( 2 )$$

$${V}_{+} = \frac{3.3 V \times r 70}{r 70 + r 60} ; \qquad Formula ( 3 )$$

Vo may refer to the output voltage from the output terminal of the first operational amplifier A1; V₊ may refer to the input voltage at the non-inverting input terminal (+) of the first operational amplifier A1; r60 may refer to the resistance of the sixth resistor R6; r70 may refer to the resistance of the seventh resistor R7; r80 may refer to the resistance of the eighth resistor R8; c30 may refer to the capacitance of the third capacitor C3; and t may refer to the reserved time for the controller 204 to reach a stable operating state, i.e., the target time mentioned earlier.

For example, assuming V₊=0.6 V and t=100 ms, the resistance and capacitance may be selected to satisfy the following conditions: r60=45 Khoms, r70=10 Khoms, r80=100 Khoms, and c30=2 μF.

According to the structures and parameter design illustrated in FIGS. 8 and 9, the audio amplifier 201 may be delayed by 100 ms before power on, thereby ensuring that the audio amplifier 201 starts operating only after the controller 204 reaches a stable state. Exemplarily, FIG. 10 illustrates a waveform of the voltage at the enable terminal EN under the effect of the power-up protection circuit 205.

Referring to FIG. 10, under the effect of the power-on protection circuit 205, in the case that the supply voltage arrives (i.e., 3.3 V), the voltage at the enable terminal EN is less than 1.2 V. At this time, the audio amplifier 201 receives a disable signal and does not enter the operating state. After the time duration t (e.g., 100 ms), the voltage at the enable terminal EN reaches 1.2 V, at which point the audio amplifier 201 receives an enable signal and enters the operating state. In other words, the voltage at the enable terminal EN of the audio amplifier 201 rises gradually, thereby ensuring that the audio amplifier 201 starts operating only after the target duration t has elapsed.

FIGS. 8 and 9 schematically illustrate two types of power-up protection circuits 205 that have a delay function. Nevertheless, the power-on protection circuit 205 may also be any another structure having the above function. For example, in some other embodiments, the power-on protection circuit 205 may be a maser-slave JK flip-flop circuit, a counter delay circuit, a digital logic delay circuit, a microprocessor delay circuit, a timer delay circuit, or the like, which is not limited in the embodiments of the present disclosure.

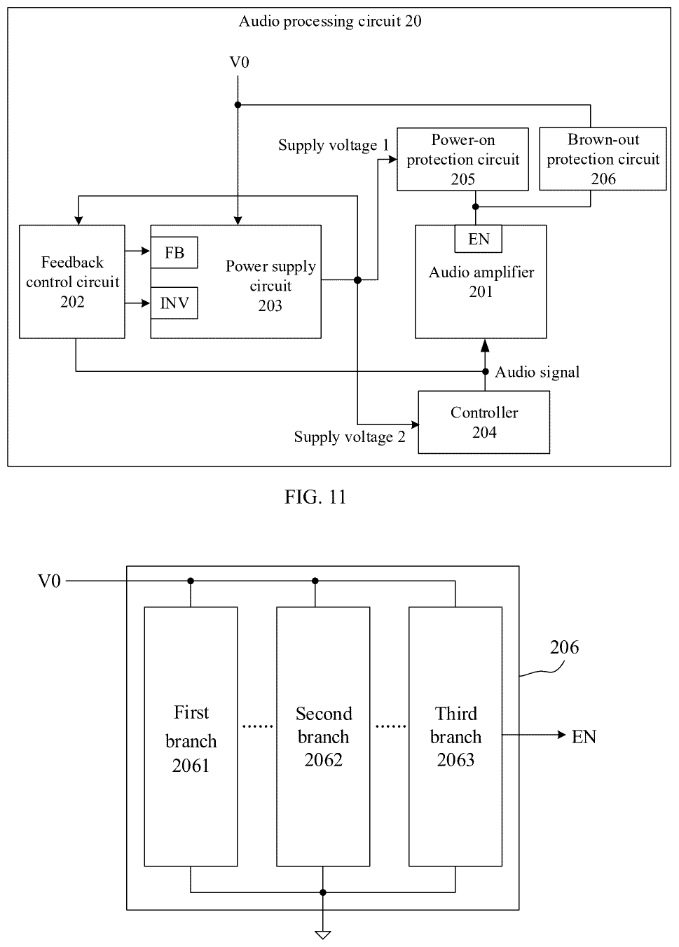

Optionally, based on FIG. 7, FIG. 11 is a schematic structural diagram of an audio processing circuit according to some embodiments of the present disclosure. As illustrated in FIG. 11, the power terminal of the power supply circuit 203 may be connected to the power supply V0, and may be further configured to provide the supply voltage to the power terminal of the audio amplifier 201 and the power terminal of the controller 204 based on a power signal supplied by the power supply V0. In the embodiments of the present disclosure, the power supply V0 may also be referred to as a power input terminal.

Exemplarily, as described above, the potential of the power signal provided by the power supply V0 may be about 5 V. On the basis that the power supply circuit 203 is a buck DC-DC converter, the power supply circuit 203 may step down the voltage of about 5 V to around 3.3 V and output the voltage to the power terminal of the audio amplifier 201 and the power terminal of the controller 204. That is, the supply voltage provided by the power supply circuit 203 for the audio amplifier 201 and the controller 204 may be about 3.3 V.

Currently, before the audio amplifier 201 and the controller 204 are powered off, the controller 204 still transmits an audio signal to the audio amplifier 201. At the instant the audio amplifier 201 and the controller 204 are powered off, since the audio signal output by the controller 204 still exists, transient fluctuations are caused to the ground potential, which subsequently causes the popping noise to the speaker.

In the embodiments of the present disclosure, still referring to FIG. 11, the audio processing circuit may further include a brown-out protection circuit 206 connected between the power supply V0 and the audio amplifier 201.

The brown-out protection circuit 206 may be configured to control the audio amplifier 201 to be powered down prior to power-down of the controller 204 in the case that the power supply stops providing the power signal.

The audio amplifier 201 may be further configured to stop driving an audio playback assembly to play audio in the case of power-down.

That is, in the embodiments of the present disclosure, one terminal of the brown-out protection circuit 206 may be connected to the power supply V0, and another terminal of the brown-out protection circuit 206 may be connected to the audio amplifier 201. Moreover, the brown-out protection circuit 206 may cause the audio amplifier 201 to be powered down before the controller 204 in the case that the entire circuit is powered off. In this way, the problem of the popping noise occurring at the moment of power-down of the audio amplifier 201 may be resolved. Accordingly, the brown-out protection circuit 206 may also be referred to as an undervoltage detection module.

Optionally, still referring to FIG. 11, in the embodiments of the present disclosure, the brown-out protection circuit 206 may be connected to the enable terminal EN of the audio amplifier 201.

The brown-out protection circuit 206 may be configured to control a voltage at the enable terminal EN of the audio amplifier 201 to be less than an enable voltage threshold to power down the audio amplifier 201 in the case that a voltage of the power signal provided by the power supply V0 is less than a supply voltage threshold. That is, the brown-out protection circuit 206 may feed back the information that the power input terminal is powered off to the audio amplifier 201 to cause the audio amplifier 201 to be powered down in a timely manner.

Optionally, in conjunction with the above description, in the embodiments of the present disclosure, in the case that the voltage of the power signal provided by the power supply V0 is less than the supply voltage threshold, the disable signal is transmitted to the enable terminal EN of the audio amplifier 201, such that the audio amplifier 201 stops operating. In the case that the voltage of the power signal provided by the power supply V0 is not less than the voltage threshold, the enable signal is transmitted to the enable terminal EN of the audio amplifier 201, such that the audio amplifier 201 operates normally.

The power voltage threshold may be used to indicate an undervoltage protection point for power-down events. That is, in the embodiments of the present disclosure, in the case that the brown-out protection circuit 206 detects that the power signal provided by the power supply V0 decreases below the undervoltage protection point, the brown-out protection circuit 206 promptly transmits the disable signal to the enable terminal EN of the audio amplifier 201, and controls the audio amplifier 201 to stop driving the audio playback assembly 10 to play audio. In this way, the problem that the audio amplifier 201 still produces sound upon power-down due to failure to predicting power-down of the power supply is resolved, and thus the “popping” noise during audio playback is prevented, thereby optimizing audio quality.

It may also be understood that after the power supply circuit 203 stops supplying power to the audio amplifier 201 for a specific time period, in the case that the power signal provided by the power supply V0 decreases to a predetermined value, the power supply V0 may stop supplying power to the controller 204. That is, the brown-out protection circuit 206 may control the power supply circuit 203 to first stop supplying power to the audio amplifier 201 and then stop supplying power to the controller 204.

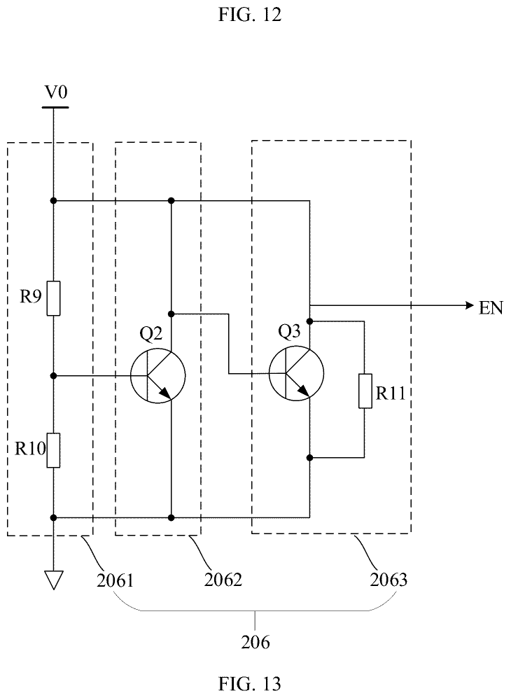

Optionally, as illustrated in FIG. 12, the brown-out protection circuit 206 may include a first branch 2061, a second branch 2062, and a third branch 2063.

One terminal of the first branch 2061 may be connected to the power supply V0, one terminal of the second branch 2062 may be connected to the first terminal of the first branch 2061, one terminal of the third branch 2063 may be connected to one terminal of the second branch 2062, another terminal of the first branch 2061, another terminal of the second branch 2062, and another terminal of the third branch 2063 are all grounded, and the third branch 2063 may be further connected to the enable terminal EN of the audio amplifier 201.

The first branch 2061 may be configured to output a first control voltage to the second branch 2062 based on the power signal provided by the power supply V0. The second branch 2062 may be configured to output a second control voltage to the third branch 2063 based on the first control voltage.

The third branch 2063 may be configured to control a voltage at the enable terminal EN of the audio amplifier 201 based on the second control voltage.

For example, the first branch 2061 may perform voltage division on the power signal provided by the power supply V0. In the case that the voltage of the power signal decreases, the voltage of the first branch 2061 may decrease, such that the second branch 2062 is in a turned-off state, and such that the second branch 2062 and the third branch 2063 are in a conducted state. Since the third branch 2063 and the audio amplifier 201 are connected to each other, in the case that the second branch 2062 and the third branch 2063 are in the conducted state, a voltage at a connection terminal between the third branch 2063 and the audio amplifier 201 may decrease, that is, a voltage at a connection terminal between the third branch 2063 and the enable terminal EN of the audio amplifier 201 is pulled down. In the case that the voltage at the enable terminal EN does not reach the enable threshold voltage that causes the audio amplifier 201 to come into effect, the audio amplifier 201 fails to normally operate.

Optionally, an a possible implementation, as illustrated in FIG. 13, the first branch 2061 may include a ninth resistor R9 and a tenth resistor R10. The second branch 2062 may include a second transistor Q2. The third branch 2063 may include a third transistor Q3 and an eleventh resistor R11.

One terminal of the ninth resistor R9, a first electrode of the second resistor Q2, and a first electrode of the third resistor Q3 may all be connected to the supply voltage V0; another terminal of the ninth resistor R9 may be connected to one terminal of the tenth resistor R10 and a control electrode of the second transistor Q2; another terminal of the tenth resistor R10, a second electrode of the second transistor Q2, and a second electrode of the third transistor Q3 may all be grounded; a control electrode of the third transistor Q3 may be connected to the first electrode of the second transistor Q2; the first electrode of the third transistor Q3 may be further connected to the enable terminal EN of the audio amplifier 201; one terminal of the eleventh resistor R11 may be connected to the first electrode of the third transistor Q3; and another terminal of the eleventh resistor R11 may be connected to the second electrode of the third transistor Q3.

As described above, the first branch 2061 achieves voltage division via a voltage division resistor therein. The second branch 2062 may be connected to the first branch 2061 via the voltage division resistor in the first branch 2061.

Since the first electrode of the second transistor Q2 on the second branch 2062 is connected to the first branch 2061 and one terminal of the first branch 2061 is grounded, a voltage at the first electrode of the second transistor Q2 may be a voltage across two terminals of the voltage division resistor. In this way, in the case that a voltage of a power signal provided by the power supply V0 decreases, the voltage across two terminals of the voltage division resistor on the first branch 2061 decreases, and a voltage at the control electrode of the second transistor Q2 on the second branch 2062 decreases accordingly, such that the second transistor Q2 may be in a turned-off state. For example, in the case that the voltage at the control electrode of the second transistor Q2 decreases to a low level of 0.4 V/0.7 V, the second transistor Q2 is in the turned-off state.

Additionally, the first electrode of the second transistor Q2 on the second branch 2062 is connected to the first electrode of the third transistor Q3 on the third branch 2063, and the second electrode of the third transistor Q3 on the third branch 2063 is connected to the audio amplifier 201, wherein a connection terminal between the second electrode of the third transistor Q3 and the audio amplifier 201 may be the enable terminal EN of the audio amplifier 201. Exemplarily, in the case that the second transistor Q2 on the second branch 2062 is in the turned-off state, a voltage at the second electrode of the second transistor Q2 increases, and hence a voltage at the first electrode of the third transistor Q3 on the third branch 2063 is pulled up, such that the third transistor Q3 is in a turned-on state. In the case that the third transistor Q3 is in the turned-on state, the voltage at the second electrode of the third transistor Q3 changes to a low level, such that the audio amplifier 201 stops operating.

That is, in the embodiments of the present disclosure, the first branch 2061 may perform voltage division on the power signal provided by the power supply V0. In the case that a voltage of the power signal provided by the power supply V0 decreases, the voltages at the ninth resistor R9 and the tenth resistor R10 upon voltage division decrease, and hence the voltage at the control electrode of the second transistor Q2 is pulled down, such that the second transistor Q2 is in the turned-off state. The first electrode of the second transistor Q2 may pull up the voltage at the control electrode of the third transistor Q3, such that the third transistor Q3 is in the turned-on state, and the first electrode of the third transistor Q3 is at a low level.

It may be understood that in the case that the power signal provided by the power supply V0 is within the range of a normal input voltage, voltage division by the voltage division resistor on the first branch 2061 may cause the voltage at the first electrode of the second transistor Q2 on the second branch 2062 to be at a high level, and hence the second transistor Q2 is in the turned-on state. In the case that the second transistor Q2 is turned on, the voltage at the first electrode of the third transistor Q3 on the third branch 2063 connected to the second electrode of the second transistor Q2 is pulled down, and the third transistor Q3 is in the turned-off state. In this case, the voltage at the enable terminal of the audio amplifier 201 connected to the second electrode of the third transistor Q3 remains at a high level, such that the audio amplifier 201 normally operates.

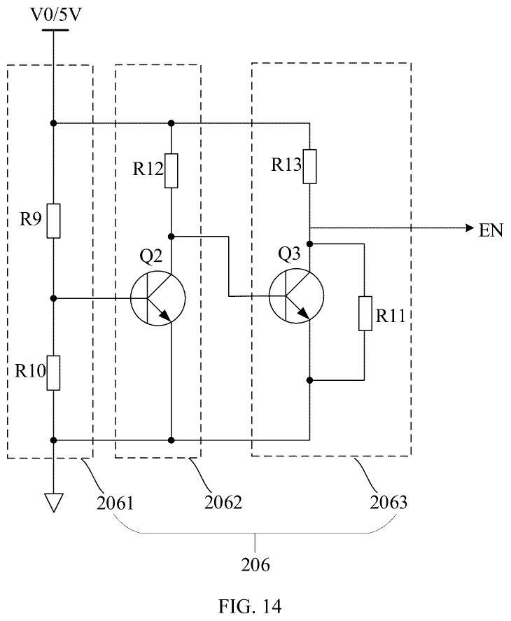

Optionally, as illustrated in FIG. 14, the second branch 2062 may further include a twelfth resistor R12. The third branch 2063 may further include a thirteenth resistor R13.

The twelfth resistor R12 may be connected in series between the power supply V0 and the first electrode of the second transistor Q2, and the thirteenth resistor R13 may be connected in series between the power supply V0 and the first electrode of the third transistor Q3.

Optionally, the second transistor Q2 and the second transistor Q3 are of the same type. For example, referring to FIG. 13 and FIG. 14, the second transistor Q2 and the third transistor Q3 may be both N-type transistors. Like the first transistor Q1, the second transistor Q2 and the third transistor Q3 herein may also be both triodes. In this case, the structure as illustrated in FIG. 13 and FIG. 14 may also be referred to as an NPN-type brown-out protection circuit 206.

Optionally, based on FIG. 14, designing of parameters for the NPN-type brown-out protection circuit 206 is described hereinafter.

First, the undervoltage protection point, for example, 4.2, may be determined based on the specifications of the power supply circuit 203, and the resistance r120 of the twelfth resistor R12 may be set to 10 Kohms to sequentially further the design of another resistances.

In the case that the second transistor Q2 is turned on, assuming that the current flowing through the second transistor Q2 is 0.5 mA, then a voltage difference between the base electrode and the emitter electrode of the second transistor Q2 may be determined as Vbe−Q2=1.2 V from the VBE-IC curve in the specification of the second transistor Q2. Therefore, it may be determined that the ratio of the resistance r90 of the ninth resistor R9 and the resistance r100 of the tenth resistor R10 is r90/r100=2.5. Based on this, in some embodiments, the resistance r90 of the ninth resistor R9 may be assigned to 10 Kohms, and the resistance r100 of the tenth resistor R10 may be assigned 25 Kohms.

In the case that the third transistor Q3 is turned off, the voltage VE at the enable terminal EN may be obtained by dividing the voltage by the thirteenth resistor R13 and the eleventh resistor R11. Assuming that the VE is 3.3 V, then ratio of the resistance r130 of the thirteenth resistor R13 to the resistance r110 of the eleventh resistor R11 may be determined as r130/r110=1/2. Based on this, in some embodiments, the resistance r130 of the thirteenth resistor R13 may be assigned to 10 Kohms, and the resistance r1 of the fifteenth resistor R15 may be assigned to 20 Kohms.

Based on the above embodiments, using a case where the power supply V0 normally provides a 5 V power signal as an example, in combination with the circuit diagram in FIG. 14, the operating principle of the brown-out protection circuit 206 is further explained as follows.

When operating normally (i.e., the power signal provided by the power supply V0 has not experienced a power drop), the ninth resistor R9 and the tenth resistor R10 may divide the voltage, such that the second transistor Q2 is turned on, and then the collector electrode of the second transistor Q2 pulls down the base electrode of the third transistor Q3, which causes the third transistor Q3 to be cut off, i.e., to be turned off. At this time, the voltage VE of the enable terminal EN may be the voltage obtained by dividing the voltage by the thirteenth resistor R13 and the eleventh resistor R11 (e.g., 3.3 V), and the audio amplifier 201 receives the enable signal and operates normally.

In the case that the power signal provided by the power supply V0 has experienced a power drop, the divided voltage across R9 and R10 decreases accordingly. In the case that the power signal decreases below the undervoltage protection point, the divided voltage across R9 and R10 causes the second transistor Q2 to be turned off. As a result, the base electrode of the third transistor Q3 is connected to the supply voltage V0 via the thirteenth resistor R13, such that the base electrode of the third transistor Q3 is pulled up and the third transistor Q3 is turned on. In this case, the enable terminal EN may be grounded via the third transistor Q3 that is turned on, that is, the enable voltage V_{E} at the enable terminal EN is pulled down, and the audio amplifier 201 receives a disable signal and stops operating. In other words, the audio amplifier 201 may be powered off before a controller 204, such that the “popping” noise caused by a brown-out event is avoided.

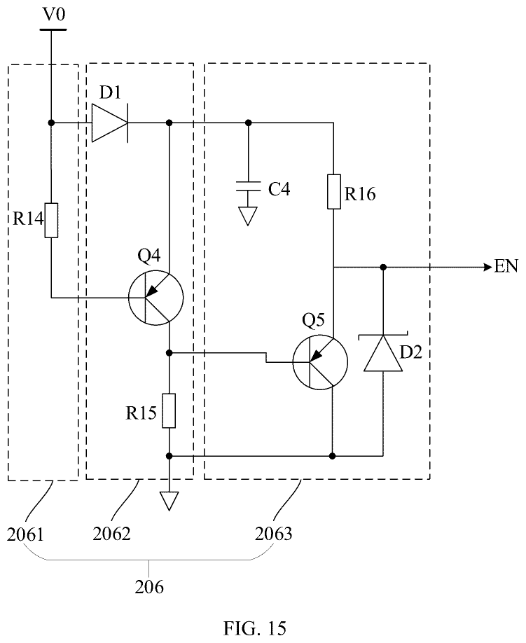

Optionally, as illustrated in FIG. 15, the first branch 2061 may include a fourteenth resistor R14. The second branch 2062 may include a first diode D1, a fourth transistor Q4, and a fifteenth resistor R15. The third branch 2063 may include a sixteenth resistor R16, a fifth transistor Q5, a fourth capacitor C4, and a second diode D2.

One terminal of the fourteenth resistor R14 and an input terminal of the first diode D1 may both be connected to the power supply V0; another terminal of the fourteenth resistor R14 may be connected to a control electrode of the fourth transistor Q4; a first electrode of the fourth transistor Q4 may be connected to an output terminal of the first diode D1, one terminal of the fourth capacitor C4, and one terminal of the sixteenth resistor R16; a second electrode of the fourth transistor Q4 may be connected to a control electrode of the fifth transistor Q5 and one terminal of the fifteenth resistor R15; another terminal of the fifteenth resistor R15, a second electrode of the fifth transistor Q5, an input terminal of the second diode D2, and another terminal of the fourth capacitor C4 may all be grounded; and a first electrode of the fifth transistor Q5 may be connected to another terminal of the sixteenth resistor R16, an output terminal of the second diode D2, and the enable terminal EN of the audio amplifier 201.

In some embodiments, the fourth transistor Q4 and the fifth transistor Q5 may be of different types. For example, referring to FIG. 15, the fourth transistor Q4 may be a P-type transistor, and the fifth transistor Q5 may be an N-type transistor. In addition, like the first transistor Q1, the fourth transistor Q4, and the fifth transistor Q5 herein may also be both triodes. Thus, the structure as illustrated in FIG. 15 may also be referred to as an NPN-type+PNP-type brown-out protection circuit 206.

Optionally, as illustrated in FIG. 15, the first diode D1 may be a standard unidirectional conductive diode, and the second diode D2 may be a Zener diode. In addition, a reverse cutoff voltage of the second diode D2 may be equal to the supply voltage for proper operation of the audio amplifier 201, such as 3.3 V as described in the above embodiments.

Designing of parameters for the NPN-type+PNP-type brown-out protection circuit 206 based on FIG. 15 is described as follows:

First, an undervoltage protection point (i.e., a potential threshold) may be determined based on the specifications of the power supply circuit 203, such as 4.2 V. Additionally, based on the transistor specifications, a voltage difference between a base electrode and an emitter electrode of the fourth transistor Q4 may be selected as Vbe−Q4=0.8 V, and a voltage difference between a base electrode and an emitter electrode of the fifth transistor Q5 may be Vbe−Q5=1.2 V.

Then, based on the connection, a ratio relationship between a resistance r140 of the fourteenth resistor R14 and a resistance r150 of the fifteenth resistor R15 may be calculated to satisfy:

$$\frac{5 - Vbe - Q 4}{r 140} \times β \times r 150 = Vbe - Q 5 \qquad Formula ( 4 )$$

β represents an amplification factor. By substituting Vbe−Q4=0.8 V and Vbe−Q5=1.2 V into Formula (4), it may be determined that r150/r140=0.0029. Based on this, in some embodiments, the resistance r140 of the fourteenth resistor R14 may be assigned to 1 Kohms, and the resistance r150 of the fifteenth resistor R15 may be assigned to 2.9 ohms.

Using a case where the power supply V0 normally provides a 5 V power signal as an example, in combination with the schematic circuit diagram in FIG. 15, the operating principle of the brown-out protection circuit 206 is further explained as follows:

During normal operation (i.e., the power signal provided by the power supply V0 has not experienced a power drop), a base voltage and a collector voltage of the fourth transistor Q4 are both 5 V, and accordingly, the fourth transistor Q4 is not turned on. Further, the base electrode of the fifth transistor Q5 is grounded via the fifteenth resistor R15, and correspondingly, the fifth transistor Q5 is not turned on either. In this case, by dividing the voltage using the second diode D2 and the sixteenth resistor R16, an enable voltage VE of about 3.3 V may be provided to the enable terminal EN, and the audio amplifier 201 receives an enable signal and operates normally.

In the case that the power signal provided by the power supply V0 has experienced a power drop, the base voltage of the fourth transistor Q4 also decreases. However, due to a storage effect of the fourth capacitor C4 and a reverse cutoff effect of the first diode D1, the collector voltage of the fourth transistor Q4 remains at a high voltage of 5 V. In the case that the power signal decreases below the undervoltage protection point, the fourth transistor Q4 is turned on, and hence, the fifth transistor Q5 is also turned on. In this case, the enable terminal EN may be grounded via the fifth transistor Q5 that is turned on, that is, the enable voltage VE at the enable terminal EN may be pulled down, and the audio amplifier 201 receives a disable signal and stops operating. In other words, the audio amplifier 201 may be powered off before a controller 204, such that the “popping” noise caused by a brown-out event is avoided.

FIG. 13 to FIG. 15 are only schematic illustrations of two types of brown-out protection circuits 206 with an undervoltage detection function. In some embodiments, the brown-out protection circuit 206 may also be of other structures, as long as the above-described functions are provided. It should be noted that the above parameter assignments and designs according to the embodiments of the present disclosure are also described for illustrative purposes.

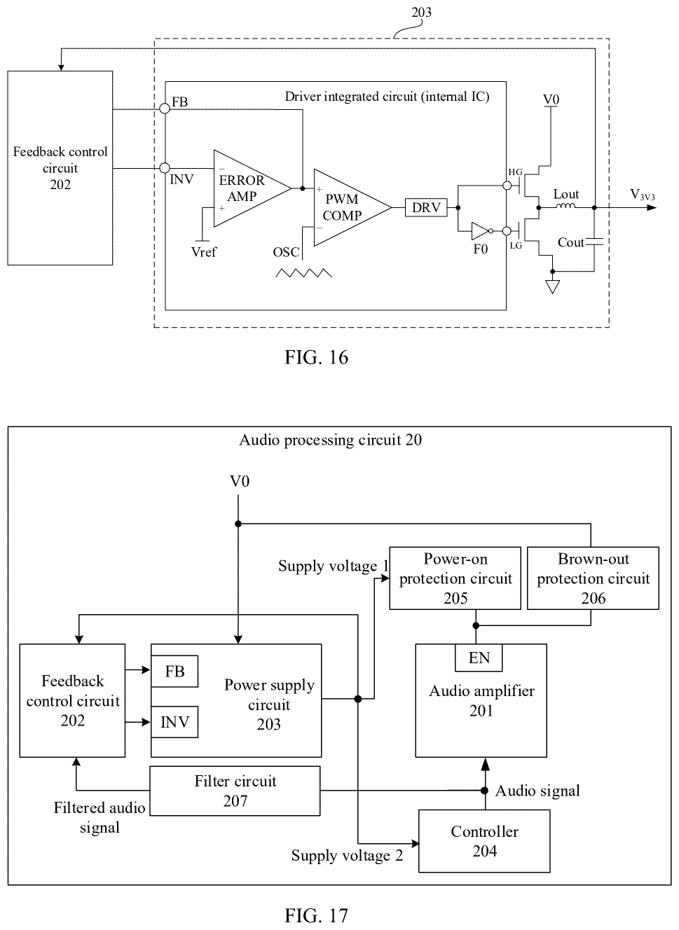

Optionally, as previously described, the power supply circuit 203 may include a buck DC converter. It can be seen with reference to FIG. 16, the buck DC converter may include a driver integrated circuit (driver IC), referred to as an internal IC, and may also include a first switch S1, a second switch S2, an output inductor Lout and an output capacitor Cout, which is referred to as a power section.

A feedback terminal of the driver chip (i.e., the internal IC), as the feedback terminal of the power supply circuit 203, is connected to the feedback control circuit 202; an input terminal of the driver chip, as the input terminal of the power supply circuit 203, is connected to the feedback control circuit 202; a first output terminal of the driver chip is connected to a control terminal of the first switch S1; a second output terminal of the driver chip is connected to a control terminal of the second switch S2; an input terminal of the first switch S1 is connected to the power supply V0; an input terminal of the second switch S2 is grounded; an output terminal of the first switch S1 and an output terminal of the second switch S2 are both connected to a first terminal of the output inductor Lout; a second terminal of the output inductor Lout, as the output terminal of the power supply circuit 203, is connected to the power terminal of the audio amplifier 201; and the output capacitor Cout may be connected in series between the input terminal of the second switch S2 and the second terminal of the output inductor Lout.

It should be noted that, based on the structure of the feedback control circuit 202 illustrated in FIG. 6, the feedback terminal FB of the driver chip may be connected to another terminal of the third resistor R3 in the first feedback sub-circuit 20221 in the feedback control circuit 202; and the input terminal INV of the driver chip may be connected to the first electrode of the first transistor Q1 in the control sub-circuit 2021 in the feedback control circuit 202. The driver chip may transmit a switch signal to the control terminal of the first switch S1 via a first output terminal HG, and transmit a switch signal to the control terminal of the second switch S2 via a second output terminal LG, such that a switch frequency of the first switch S1 and the second switch S2 is controlled, such that the purpose of stepping down a power supply signal provided by the power supply V0 to an desired supply voltage is achieved.

In some embodiments, as illustrated in FIG. 16, the first switch S1 and the second switch S2 may be both N-type field-effect transistors. Accordingly, taking the first switch S1 as an example, a control electrode of the first switch S1 may be a gate electrode, a first electrode of the first switch S1 may be a source electrode, and a second electrode of the first switch S1 may be a drain electrode; and the same applies to the second switch S2.

In addition, FIG. 16 schematically illustrates an internal structure of a driver chip. Referring to FIG. 16, the driver chip includes a second operational amplifier, a comparator, a driver, and an inverter F0 that are successively connected.

The second operational amplifier, for example, may be an error amplifier (ERROR AMP), the comparator may be a pulse width modulation comparator (PWM CMP), and the driver may be referred to as a driver section (DRV).

An inverting input terminal (−) of the ERROR AMP may be connected to an input terminal INV; a non-inverting input terminal (+) of the ERROR AMP may be connected to a reference power terminal Vref to receive a reference power signal provided by the reference power terminal Vref; the reference power signal may be a preset fixed value; an output terminal of ERROR AMP may be connected to a non-inverting input terminal (+) of the PWM CMP; the non-inverting input terminal (+) of the PWM CMP may also be connected to the feedback terminal FB; an inverting input terminal (−) of the PWM CMP may be connected to an oscillator (OSC) to receive an oscillation signal generated by the OSC; an output terminal of the PWM CMP may be connected to an input terminal of a driver section (DRV); and an output terminal of the DRV may be directly connected to the first output terminal HG and indirectly connected to the second output terminal LG via an inverter F0.

That is, in the embodiments of the present disclosure, the power supply circuit 203 may regulate the voltage provided to the audio amplifier 201 in a timely manner according to the voltage at the connection terminal between the feedback control circuit 202 and the power supply circuit 203 using an internal amplifier and comparator.

In some embodiments, as previously described, an inverting input terminal (−) of the second operational amplifier connected to the second feedback sub-circuit 20222 may be the connection terminal between the feedback control circuit 202 and the power supply circuit 203, and then the voltage at the inverting input terminal (−) of the second operational amplifier is a regulated target voltage.

Exemplarily, the voltage of the second feedback sub-circuit 20222 is the same as the voltage at the inverting input terminal (−) of the second operational amplifier. Therefore, in the case that the current of the second feedback sub-circuit 20222 changes, the voltage at the inverting input terminal (−) of the second operational amplifier changes accordingly. For example, in the case that the current of the second feedback sub-circuit 20222 decreases, the voltage at the inverting input terminal (−) of the second operational amplifier decreases; and in the case that the voltage at the inverting input terminal (−) of the second operational amplifier is less than the voltage at a non-inverting input terminal (+), the voltage output from the second operational amplifier increases. In the case that the current of the second feedback sub-circuit 20222 increases, the voltage at the inverting input terminal (−) of the second operational amplifier increases; and in the case that the voltage at the inverting input terminal (−) of the second operational amplifier is greater than the voltage at the non-inverting input terminal (+), the voltage output from the second operational amplifier decreases.

It should be noted that, in the case that the voltage at the inverting input terminal (−) is equal to the voltage at the non-inverting input terminal (+) of the second operational amplifier in the power supply circuit 203, the power supply circuit 203 may stop regulating the supply voltage provided to the audio amplifier 201.

In some other embodiments, an output terminal of the second operational amplifier is connected to a non-inverting input terminal (+) of the comparator, such that the voltage output from the second operational amplifier is the same as the voltage at the non-inverting input terminal+ of the comparator.

Exemplarily, in the case that the voltage output from the second operational amplifier increases, the voltage at the non-inverting input terminal (+) of the comparator also increases, and a duty cycle of a pulse width modulation (PWM) increases. In the case that the voltage output from the second operational amplifier decreases, the voltage at the inverting input terminal (−) of the comparator decreases accordingly, and the duty cycle of the PWM decreases. It should be noted that the supply voltage provided to the audio amplifier 201 by the power supply circuit 203 may be increased or decreased by the change in a magnitude of the duty cycle of the PWM.

That is, in the case that an amplitude of the audio signal increases, a collector current Ic of a first transistor Q1 increases, and a current I2 decreases. As a result, a voltage at an INV pin decreases and is less than the voltage of the reference power signal provided at the reference power terminal Vref. At this time, in the case that the driver chip detects that the voltage at the INV pin is less than the voltage of the reference power signal, an output voltage of the ERROR AMP increases, the voltage obtained at the non-inverting input terminal of the PWM COMP increases, and the duty cycle of the output PWM becomes larger. In the case that the duty cycle of the PWM increases, the voltage output from the power supply circuit 203 also increases, which causes both currents I1 and I2 to increase. In the case that the voltage at the INV pin increases until the voltage is equal to the voltage of the reference power signal, the regulation stops, and the voltage output from the power supply circuit 203 is stabilized at a value upon regulation. At this stage, the regulation process, in which the voltage output from the power supply circuit 203 increases due to the increase of the amplitude of the audio signal, is completed. In the case that the amplitude of the audio signal decreases, the collector current Ic of the first transistor Q1 decreases, and the current I2 increases, and then the voltage at the INV pin rises and is greater than the voltage of the reference power signal. In this case, in the case that the driver chip detects that the INV voltage is greater than the voltage of the reference power signal, an output voltage of the ERROR AMP decreases, such that the voltage obtained at the non-inverting input terminal of the PWM COMP decreases, and the duty cycle of the PWM becomes smaller. In the case that the duty cycle of the PWM decreases, the voltage output from the power supply circuit 203 decreases. This results in a decrease in the currents I1 and I2, and an increase in the voltage at the INV pin until the voltage is equal to the voltage of the reference power signal. In this case, the regulation stops, and the voltage output from the power supply circuit 203 is stabilized at the value upon regulation. At this point, the regulation process, in which the output voltage of the power supply circuit 203 decreases due to the reduction in the audio signal amplitude, is complete.

Optionally, based on FIG. 11, FIG. 17 is a schematic structural diagram of an audio processing circuit according to some embodiments of the present disclosure. As illustrated in FIG. 17, the audio processing circuit according to the present disclosure may further include a filter circuit 207, connected between the input terminal of the audio amplifier 201 and the feedback control circuit 202. That is, an input terminal of the filter circuit 207 may be connected to the input terminal of the audio amplifier 201 (that is, the output terminal of the controller 204), and an output terminal of the filter circuit 207 may be connected to the feedback control circuit 202.

The filter circuit 207 may be configured to filter the audio signal, and transmit a filtered audio signal to the feedback control circuit 202. Specifically, the audio signal received by the feedback control circuit 202 may be an audio signal obtained after the filter circuit 207 filters the audio signal generated by controller 204.

Optionally, the filter circuit 207 may filter out high-frequency noise signals in the audio signal during the filtering process. It has been found through testing that, in the case that the audio signal generated by the controller 204 contains high-frequency noise, the noise may continuously trigger the feedback control circuit 202 to regulate the supply voltage provided by the power supply circuit 203 within a high frequency band, which may result in an unstable output of the power supply circuit 203. Moreover, as described above, the noise that is higher than 20 KHz has exceeded the range of audibility of the human ear. That is, the audio signal containing such high-frequency noise is not beneficial to the entire audio processing circuit. Thus, by introducing the filter circuit 207 between the controller 204 and the feedback control circuit 202 to filter out these unhelpful high-frequency noise signals, the stability of the output of the power supply circuit 203 may be further ensured. That is, the power supply circuit 203 is ensured to supply the supply voltage such that the audio amplifier 201 drives the audio playback assembly to play audio, thereby further optimizing sound quality.

It should be noted that, referring to FIG. 4, based on the feedback control circuit 202 including the control sub-circuit 2021 and the feedback sub-circuit 2022, the filter circuit 207 may be connected to the control sub-circuit 2021 in the feedback control circuit 202.

Additionally, on the basis that the filter circuit 207 is included, as seen from FIG. 6, one terminal of the first resistor R1 may be indirectly connected to the input terminal of the audio amplifier 201 via the filter circuit 207. That is, one terminal of the first resistor R1 may be connected to the output terminal of the filter circuit 207, and the input terminal of the filter circuit 207 may be connected to the input terminal of the audio amplifier 201. The audio signal received at one terminal of the first resistor R1 may be the audio signal after the filter circuit 207 has filtered and processed the audio signal generated by the controller 204.

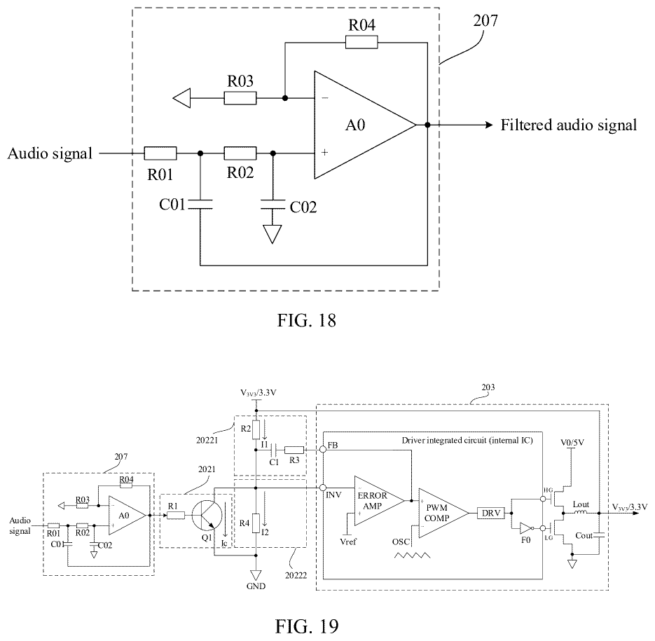

In some embodiments, the filter circuit 207 may include a second-order Butterworth low-pass filter. That is, as illustrated in FIG. 18, the filter circuit 207 may include one operational amplifier A0, four resistors R01, R02, R03, and R04, and two capacitors COT and C02.

A first terminal of the resistor R01 is connected to an output terminal of a controller 204 (not illustrated in FIG. 18) to receive the audio signal; a second terminal of resistor R01 is connected to a first terminal of the capacitor COT and a first terminal of the resistor R02; a second terminal of the capacitor COT is connected to an output terminal of an operational amplifier A01; a second terminal of the resistor R02 is connected to a first terminal of the capacitor C02 and a non-inverting input terminal (+) of the operational amplifier A01; a second terminal of the capacitor C02 is grounded; a first terminal of the resistor R03 is grounded, and a second terminal of the resistor R03 is connected to a first terminal of the resistor R04 and an inverting input terminal (−) of the operational amplifier A01; and a second terminal of the resistor R04 is connected to the output terminal of the operational amplifier A01, and the output terminal of the operational amplifier A01 is connected to a control terminal of a control sub-circuit 042, that is, the output terminal of the operational amplifier A01 is connected to one terminal of a first resistor R1 in the control sub-circuit 042.

By configuring a second-order Butterworth low-pass filter as the filter circuit 207, high-frequency noise signals greater than a cutoff frequency may be better suppressed. This effectively ensures, by filtering out high-frequency noise, that the audio signal received by the feedback control circuit 202 does not include high-frequency noise. The structure of the filter circuit 207 described here is only illustrative. For example, in some other embodiments, the filter circuit 207 may also be an LC filter circuit.

Optionally, in combination with FIG. 6, FIG. 16 and FIG. 18, FIG. 19 also illustrates a schematic circuit diagram of a further audio processing circuit. On the basis of FIG. 19, as described above, the principle of solving the “howling” noise by the audio processing circuit described in the embodiments of the present disclosure is further described as follows.

In the case that the voltage of the filtered audio signal increases, the collector current Ic of the first transistor Q1 increases accordingly, and then the current I2 flowing through the fourth resistor R4 decreases accordingly, and the voltage at the input terminal INV of the power supply circuit 203 decreases accordingly. In the case that the driver chip detects that the voltage at the input terminal INV is less than the voltage at a reference power signal terminal provided by the reference power terminal Vref, the voltage output from the output terminal of the error amplifier ERROR AMP to the non-inverting input terminal (+) of the pulse-width modulation comparator PWM CMP increases. The higher the voltage received at the non-inverting input terminal (+) of the pulse-width modulation comparator PWM CMP, the larger the duty cycle of the PWM output at the output terminal of the pulse-width modulation comparator PWM CMP. On the premise that the duty cycle increases, that is, the power supply circuit 203 may increase the supply voltage output via an output terminal V_{3V3} based on the power signal provided by the power supply V0. With the increase of the supply voltage, the current I1 flowing through the second resistor R2 and the current I2 flowing through the fourth resistor R4 increase accordingly, which in turn causes the voltage at the input terminal INV to increase. In the case that the voltage at the input terminal INV increases to be equal to the voltage of the reference power signal, the regulation of the supply voltage may stop, and the supply voltage output from the power supply circuit 203 is stabilized at the value upon regulation, which is positively correlated with the voltage of the audio signal. At this stage, the regulation process, in which the supply voltage increases due to the increase of the audio signal, is completed.

In the case that the voltage of the filtered audio signal decreases, the collector current Ic of the first transistor Q1 decreases accordingly, and then the current I2 flowing through the fourth resistor R4 increases accordingly, and the voltage at the input terminal INV of the power supply circuit 203 increases accordingly. In the case that the driver chip detects that the voltage at the input terminal INV is greater than the voltage at a reference power signal terminal provided by the reference power terminal Vref, the voltage output from the output terminal of the error amplifier ERROR AMP to the non-inverting input terminal (+) of the pulse-width modulation comparator PWM CMP decreases. The lower the voltage received at the non-inverting input terminal (+) of the pulse-width modulation comparator PWM CMP, the smaller the duty cycle of the PWM output at the output terminal of the pulse-width modulation comparator PWM CMP. On the premise that the duty cycle decreases, that is, the power supply circuit 203 may decrease the supply voltage output via an output terminal V_{3V3} based on the power signal provided by the power supply V0. With the decrease of the supply voltage, the current I1 flowing through the second resistor R2 and the current I2 flowing through the fourth resistor R4 decrease accordingly, which in turn causes the voltage at the input terminal INV to decrease. In the case that the voltage at the input terminal INV decreases to the voltage equal to the reference power signal, the regulation of the supply voltage may stop, and the supply voltage output from the power supply circuit 203 is stabilized at the value upon regulation, which is positively correlated with the voltage of the audio signal. At this stage, the regulation process, in which the supply voltage decreases due to the decrease of the audio signal, is completed.

It may be understood that, in some embodiments, the feedback sub-circuit 2022 may be included in the power supply circuit 203. That is, the power supply circuit 203 may include the power section (the first switch S1, the second switch S2, the output inductor Lout, and the output capacitor Cout), the feedback sub-circuit 2022, and the internal IC.

Optionally, based on the above embodiments, the elements and signal parameters in the circuit illustrated in FIG. 19 are further described as follows.
1. The potential of the reference power signal provided by the reference power terminal Vref may be determined by specifications of the power supply circuit, such as generally 0.6 V. Additionally, in the case that the supply voltage is stable (i.e., the power supply circuit 203 operates in a steady state), the voltage at the input terminal INV should be equal to the voltage of the reference power signal, for example, both 0.6 V. Based on this, resistances of the second resistor R2 and the fourth resistor R4 may be assigned as follows: the resistance r20 of the second resistor R2 is 10 Kohms, and the resistance r40 of R4 is 2.2 Kohms. Furthermore, it may be further determined that the current I2 flowing through the fourth resistor R4 is approximately equal to 270 microamps (μA).
2. It may be determined by actual testing that the supply voltage output by the power supply circuit 203 via the output terminal V_{3V3} is within an regulatable voltage range of 3.3 V to 3.6 V. Based on this, in combination with the above determined resistance r20 (10 Kohms) of the second resistor R2 and the resistance r40 (2.2 Kohms) of the fourth resistor R4, it may be determined that the current I1 flowing through the second resistor R21 may be within a current range of 270 μA to 300 μA; and the collector current Ic flowing through the first transistor Q1 may be within a current range of 0 to 30 μA.
3. Based on the specifications of a triode, it may be determined that a current amplification factor HFE of the first transistor Q1 is approximately 10, and the current flowing through the first resistor R1 may range from 0 to 3 μA.
4. Based on the above description, it may be determined that the voltage of the audio signal transmitted to the first resistor R1 is within the range of 0 to 3.3 V, and the resistance r10 of the first resistor R1 is 1.1 Mohms.
5. The second-order Butterworth low-pass filter may be designed in the following manner:

First, a transfer function analysis of the circuit illustrated in FIG. 19 may be performed to derive Formula (5):

$$H ( s ) = \frac{{A}_{F} / r 010 r 020 c 010 c 020}{\begin{matrix}{s}^{2} + s ( \frac{1}{r 010 c 10} + \frac{1}{r 020 c 010} + \frac{1 - {A}_{F}}{r 020 c 020} ) + \\ \frac{1}{r 010 r 020 c 010 c 020}\end{matrix}} ; \qquad Formula ( 5 )$$

r010 represents a resistance of the resistor R01; r020 represents a resistance of the resistor R02; c010 represents a capacitance of the capacitor C01; c020 represents a capacitance of the capacitor C02; A_{F} represents a gain of the operational amplifier A0; and s represents a complex variable of the Laplace transform, which denotes a complex frequency domain.

A denormalized transfer function H(s) satisfies Formula (6):

$$H ( s ) = \frac{{H}_{0} {W}_{0}^{2}}{{s}^{2} + \sqrt{2} s {W}_{0} + {W}_{0}^{2}} ; \qquad Formula ( 6 )$$

W₀ represents an angular frequency of the operational amplifier A0.

Formulas (7), (8), and (9) may be obtained from the above Formulas (5) and (6):

$${W}_{0}^{2} = \frac{1}{r 010 r 020 c 010 c 020} ; \qquad Formula ( 7 )$$

$${H}_{0} {W}_{0}^{2} = \frac{{A}_{F}}{r 010 r 020 c 010 c 020} ; \qquad Formula ( 8 )$$

$$\sqrt{2} {W}_{0} = \frac{1}{r 010 c 010} + \frac{1}{r 020 c 010} + \frac{1 - {A}_{F}}{r 020 c 020} ; \qquad Formula ( 9 )$$

In some embodiments, c020 may be set to be equal to kc010. Based on this, from Formulas (7), (8), and (9), it may be concluded that H₀=A_{F}, and Formulas (10) and (11) are obtained.

$${kW}_{0}^{2} c 01 {0}^{2} r 02 {0}^{2} - \sqrt{2} {W}_{0} c 010 r 020 + 1 = 0 ; \qquad Formula ( 10 )$$

$$r 010 ( r 020 ) = \frac{1 \pm \sqrt{1 - 2 k}}{\sqrt{2} {kW}_{0} c 010} ; \qquad Formula ( 11 )$$

Afterwards, based on a required cutoff frequency f0=20 KHz, a gain Af may be set to 1, and thus it may be determined that H₀=A_{F}=1. Based on the above, it is apparent the resistance r040 of the resistor R04 is equal to (r010+r020); and the resistance r030 of the resistor R03 is equal to ∞, which indicates an open circuit. In some embodiments, the capacitance c010 of the capacitor C01 may take 2.2 nanofarads (nF). Since the resistance r020 of the resistor R02 in formula (9) should have a real root, the constant k≤1/2. In the case that k takes a small value, the cutoff frequency may drift, the operation of the circuit may be unstable, and distortion may be caused, such that k is set to k=1/2 according to the embodiments of the present disclosure.

That is, in the embodiments of the present disclosure, k may be designed to k=0.5; the capacitance c010 of the capacitor C01 may be designed to 2200 picofarads (pF); the capacitance c020 of the capacitor C02 may be designed to 1100 pF; the resistance r010 of the resistor R01 may be designed to 5 Kohms; the resistance r020 of the resistor R02 may be designed to 5 Kohms; the resistance r030 of the resistor R03 may be designed to ∞; and the resistance r040 of the resistor R04 may be designed to 10 Kohms.

Optionally, as previously described, the audio amplifier 201 may be a digital power amplifier chip including a switch amplifier, i.e., a class D audio power amplifier as previously described.

Optionally, as previously described, the controller 204 may include a microcontroller unit MCU.

Based on the above description, it is apparent that according to the embodiments of the present disclosure, by using the feedback control circuit 202 in combination with the filter circuit 207, stability of the output by the power supply circuit 203 is ensured, and then the occurrence of “howling” is avoided; the power-on protection circuit 205 may control the power supply circuit 203 to first power up the controller 204, and then power up the audio amplifier 201 in the case that the power supply circuit 203 is powered up, such that the audio amplifier 201 enters the operating state after the controller 204 is operating stably, and the occurrence of power-up “popping” is avoided; in addition, the brown-out protection circuit 206 may timely detect whether the power supply V0 has failed, and in the case that the power supply V0 decreases below the undervoltage protection point, the audio amplifier 201 is promptly shut down, i.e., the audio amplifier 201 is controlled to stop operating before the controller 204, thereby avoiding the occurrence of the power-down “popping” noise. In this way, the purpose of reliably optimizing the sound quality may be achieved. Thus, the audio processing circuit described in the embodiments of the present disclosure may also be referred to as an audio processing circuit for processing audio.

In summary, the embodiments of the present disclosure provide an audio processing circuit. The audio processing circuit adds a feedback control circuit between the power supply circuit and the audio amplifier, such that the feedback control circuit is allowed to control the regulation of the supply voltage provided to the audio amplifier based on changes of the amplitude of the audio signal received by the audio amplifier. In this way, in the case that the amplitude of the audio signal changes, the feedback control circuit is capable of figuring out the appropriate supply voltage matched with the audio amplifier for the audio amplifier, such that the problem of howling that occurs in response to the changes of the amplitude of the audio signal in the audio playback module is resolved, and the sound quality during playback is optimized.

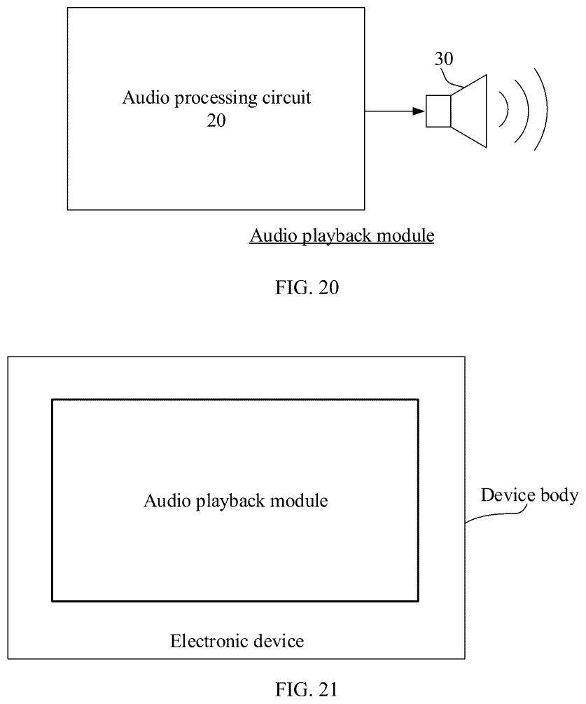

FIG. 20 is a schematic structural diagram of an audio playback module according to some embodiments of the present disclosure. As illustrated in FIG. 20, the audio playback module includes an audio playback assembly 30, and the audio processing circuit 20 as described in the above embodiments.

The audio processing circuit 20 is connected to the audio playback assembly 30, and is configured to drive the audio playback assembly 30 to play audio. For example, the audio playback assembly 30 may be a speaker as illustrated in FIG. 20.

Optionally, in some embodiments, the audio playback module may further include a power supply assembly J1, wherein the power supply assembly may be connected to the audio processing circuit 20, and is configured to supply power to the audio processing circuit 20. For example, the power supply assembly J1 may be connected to the power supply V0 connected to the audio processing circuit 20, to supply a 5 V power signal to the power supply V0.

FIG. 21 is a schematic structural diagram of an electronic device according to some embodiments of the present disclosure. As illustrated in FIG. 21, the electronic device may include a device body, and the audio playback module (as illustrated in FIG. 20) in the device body. That is, the electronic device may be integrated with an audio playback function.

Optionally, the electronic device according to the embodiments of the present disclosure may be a smart phone, a tablet computer, a flexible display device, a TV set, a display, or any other product having the display function; or may be a refrigerator, a washing machine, a robotic vacuum cleaner, a floor washer, a cooking robot, an air purifier, and any other smart home appliance.

It should be noted that the terms used herein are for the purpose of describing particular embodiments of the present disclosure, and are not intended to limit the present disclosure. Unless otherwise specified, the technical terms and scientific terms used in the embodiments of the present disclosure shall express general meanings that may be understood by a person skilled in the art.

In addition, in the embodiments of the present disclosure, the terms “first” and “second” are merely for the illustration purpose, and shall not be construed as indicating or implying a relative importance. Unless otherwise specified, the term “plurality of” refers to two or more than two.

Likewise, the article like “a” or “an” does not imply a specific quantity but rather indicate “at least one.”

Such words as “include,” “comprise,” and derivations thereof indicate that a member or entity in front of the word covers listed elements or units or the like that follow the word, but such words do not exclude other elements or units.

The terms “above,” “below,” “left,” and “right” are used solely to indicate relative positional relationships. When the absolute position of the described object changes, the relative positional relationships may also change accordingly.

Described above are merely preferred embodiments of the present disclosure, but are not intended to limit the present disclosure. Any modification, equivalent replacement, or improvement made without departing from the spirit and principle of the present disclosure should fall within the protection scope of the present disclosure.

What is claimed is:

1. An audio processing circuit, comprising: an audio amplifier, a feedback control circuit, and a power supply circuit; wherein
the feedback control circuit is connected to an input terminal of the audio amplifier and an input terminal of the power supply circuit, and an output terminal of the power supply circuit is connected to a power terminal of the audio amplifier; and
the feedback control circuit is configured to control, based on an audio signal received at the input terminal of the audio amplifier, the power supply circuit to regulate a supply voltage provided to the power terminal of the audio amplifier, and a magnitude of the supply voltage upon regulation is positively correlated with an amplitude of the audio signal.

2. The audio processing circuit according to claim 1, wherein
the feedback control circuit is configured to regulate an input voltage at the input terminal of the power supply circuit based on the audio signal, wherein a magnitude of the input voltage upon regulation is negatively correlated with the amplitude of the audio signal; and
the power supply circuit is configured to regulate, based on the input voltage upon regulation, the supply voltage provided to the power terminal of the audio amplifier.

3. The audio processing circuit according to claim 2, wherein the feedback control circuit is connected to the output terminal of the power supply circuit and a feedback terminal of the power supply circuit, and is further configured to feed back the supply voltage provided by the power supply circuit to the power terminal of the audio amplifier to the feedback terminal of the power supply circuit; and the feedback control circuit comprises a control sub-circuit and a feedback sub-circuit; and wherein
the control sub-circuit is connected to the input terminal of the power supply circuit via the feedback sub-circuit, the control sub-circuit is further connected to the input terminal of the audio amplifier, and the feedback sub-circuit is further connected to the output terminal of the power supply circuit and the feedback terminal of the power supply circuit;
the control sub-circuit is configured to regulate the input voltage at the input terminal of the power supply circuit based on the audio signal; and
the feedback sub-circuit is configured to feed back the supply voltage provided by the power supply circuit to the power terminal of the audio amplifier to the feedback terminal of the power supply circuit.

4. The audio processing circuit according to claim 3, wherein the control sub-circuit comprises a first resistor and a first transistor; and
one terminal of the first resistor is connected to the input terminal of the audio amplifier, another terminal of the first resistor is connected to a control electrode of the first transistor, a first electrode of the first transistor is connected to the input terminal of the power supply circuit via the feedback sub-circuit, and a second electrode of the first transistor is grounded.

5. The audio processing circuit according to claim 3, wherein the feedback sub-circuit comprises a first feedback sub-circuit and a second feedback sub-circuit;
a first terminal of the first feedback sub-circuit is connected to the output terminal of the power supply circuit; a second terminal of the first feedback sub-circuit is connected to the feedback terminal of the power supply circuit; and a third terminal of the first feedback sub-circuit is connected to the control sub-circuit, the second feedback sub-circuit, and the input terminal of the power supply circuit; and
a magnitude of a current of the control sub-circuit is positively correlated with the amplitude of the audio signal, a magnitude of a current of the second feedback sub-circuit is negatively correlated with the magnitude of the current of the control sub-circuit, and the input voltage at the input terminal of the power supply circuit is positively correlated with the magnitude of the current of the second feedback sub-circuit; and
wherein the first feedback sub-circuit comprises a second resistor, a third resistor, and a first capacitor; and the second feedback sub-circuit comprises a fourth resistor; and
one terminal of the second resistor is connected to the output terminal of the power supply circuit; another terminal of the second resistor is connected to one terminal of the first capacitor, one terminal of the fourth resistor, the control sub-circuit, and the input terminal of the power supply circuit; another terminal of the first capacitor is connected to a terminal of the third resistor; another terminal of the third resistor is connected to the feedback terminal of the power supply circuit; and another terminal of the fourth resistor is grounded.

6. (canceled)

7. The audio processing circuit according to claim 1, wherein the audio processing circuit further comprises a controller, an output terminal of the controller is connected to the input terminal of the audio amplifier, and the output terminal of the power supply circuit is further connected to a power terminal of the controller;
the power supply circuit is further configured to provide the supply voltage to the power terminal of the controller;
the controller is further configured to generate the audio signal based on a stored digital signal, and output the audio signal to the input terminal of the audio amplifier in the case of power-on; and
the audio amplifier is configured to drive, based on the audio signal, a connected audio playback assembly to play audio in the case of power-on.

8. The audio processing circuit according to claim 7, further comprising: a power-on protection circuit, connected between the output terminal of the power supply circuit and the audio amplifier; and
wherein the power-on protection circuit is configured to control the audio amplifier to be powered on in the case of power-on of the controller.

9. The audio processing circuit according to claim 8, wherein
the power-on protection circuit is connected to an enable terminal of the audio amplifier;
the power-on protection circuit is configured to perform voltage division on the supply voltage provided by the power supply circuit to the power terminal of the audio amplifier, and output a divided voltage to the enable terminal of the audio amplifier to power on the audio amplifier; and
the audio amplifier is configured to drive, based on the audio signal, the audio playback assembly to play back the audio in a case that a voltage at the enable terminal of the audio amplifier is greater than an enable voltage threshold; and
wherein a duration for which the voltage at the enable terminal is greater than the enable voltage threshold is greater than or equal to a duration required for the controller to enter a stable operating state.

10. The audio processing circuit according to claim 9, wherein
the power-on protection circuit comprises a passive integrator, and the passive integrator comprises a fifth resistor and a second capacitor; one terminal of the fifth resistor is connected to the output terminal of the power supply circuit, another terminal of the fifth resistor is connected to one terminal of the second capacitor and an enable terminal of the power supply circuit, and another terminal of the second capacitor is grounded; or
the power-on protection circuit comprises an active integrator, and the active integrator comprises a sixth resistor, a seventh resistor, an eighth resistor, a third capacitor, and a first operational amplifier; and one terminal of the sixth resistor is connected to the output terminal of the power supply circuit, another terminal of the sixth resistor is connected to one terminal of the seventh resistor and a non-inverting input terminal of the first operational amplifier, another terminal of the seventh resistor is connected to one terminal of the eighth resistor and is grounded, another terminal of the eighth resistor is connected to an inverting input terminal of the first operational amplifier and one terminal of the third capacitor, another terminal of the third capacitor is connected to an output terminal of the first operational amplifier, and the output terminal of the first operational amplifier is further connected to an enable terminal of the power supply circuit.

11. The audio processing circuit according to claim 7, wherein the power terminal of the power supply circuit is connected to a power supply, and the power supply circuit is further configured to provide the supply voltage to the power terminal of the audio amplifier and the power terminal of the controller based on a power signal provided by the power supply;
the audio processing circuit further comprises a brown-out protection circuit, connected between the power supply and the audio amplifier;
the brown-out protection circuit is configured to control the audio amplifier to be powered down prior to power-down of the controller in the case that the power supply stops providing the power signal; and
the audio amplifier is configured to stop driving the audio playback assembly to play audio in the case of power-down.

12. The audio processing circuit according to claim 11, wherein
the brown-out protection circuit is connected to an enable terminal of the audio amplifier; and
the brown-out protection circuit is configured to control a voltage at the enable terminal of the audio amplifier to be less than an enable voltage threshold to power down the audio amplifier in the case that a voltage of the power signal provided by the power supply is less than a supply voltage threshold.

13. The audio processing circuit according to claim 12, wherein the brown-out protection circuit comprises a first branch, a second branch, and a third branch;
one terminal of the first branch is connected to the power supply; one terminal of the second branch is connected to the one terminal of the first branch; one terminal of the third branch is connected to the one terminal of the second branch; another terminal of the first branch, another terminal of the second branch, and another terminal of the third branch are all grounded; and the third branch is further connected to the enable terminal of the audio amplifier;
the first branch is configured to output a first control voltage to the second branch based on the power signal provided by the power supply;
the second branch is configured to output a second control voltage to the third branch based on the first control voltage; and
the third branch is configured to control the voltage at the enable terminal of the audio amplifier based on the second control voltage.

14. The audio processing circuit according to claim 13, wherein the first branch comprises a ninth resistor and a tenth resistor; the second branch comprises a second transistor; the third branch comprises a third transistor and an eleventh resistor; and the second transistor and the third transistor are of a same type; and
wherein one terminal of the ninth resistor, a first electrode of the second transistor, and a first electrode of the third transistor are all connected to the power supply; another terminal of the ninth resistor is connected to one terminal of the tenth resistor and a control electrode of the second transistor; another terminal of the tenth resistor, a second electrode of the second transistor, and a second electrode of the third transistor are all grounded; a control electrode of the third transistor is connected to the first electrode of the second transistor; the first electrode of the third transistor is further connected to the enable terminal of the audio amplifier; one terminal of the eleventh resistor is connected to the first electrode of the third transistor; and another terminal of the eleventh resistor is connected to the second electrode of the third transistor; and
wherein the second branch further comprises a twelfth resistor and the third branch further comprises a thirteenth resistor; and
wherein the twelfth resistor is connected in series between the power supply and the first electrode of the second transistor, and the thirteenth resistor is connected in series between the power supply and the first electrode of the third transistor.

15. (canceled)

16. The audio processing circuit according to claim 13, wherein the first branch comprises a fourteenth resistor; the second branch comprises a first diode, a fourth transistor, and a fifteenth resistor; and the third branch comprises a sixteenth resistor, a fifth transistor, a fourth capacitor and a second diode, and the fourth transistor and the fifth transistor are of different types; and
wherein one terminal of the fourteenth resistor and an input terminal of the first diode are both connected to the power supply; another terminal of the fourteenth resistor is connected to a control electrode of the fourth transistor; a first electrode of the fourth transistor is connected to an output terminal of the first diode, one terminal of the fourth capacitor, and one terminal of the sixteenth resistor; a second electrode of the fourth transistor is connected to a control electrode of the fifth transistor and one terminal of the fifteenth resistor; another terminal of the fifteenth resistor, a second electrode of the fifth transistor, an input terminal of the second diode, and another terminal of the fourth capacitor are all grounded; and a first electrode of the fifth transistor is connected to another terminal of the sixteenth resistor, an output terminal of the second diode, and the enable terminal of the audio amplifier.

17. The audio processing circuit according to claim 1, wherein the power supply circuit comprises a buck DC-DC converter, and the buck DC-DC converter comprises a driver chip, a first switch, a second switch, an output inductor, and an output capacitor; and
wherein a feedback terminal of the driver chip, as a feedback terminal of the power supply circuit, is connected to the feedback control circuit; an input terminal of the driver chip, as the input terminal of the power supply circuit, is connected to the feedback control circuit; a first output terminal of the driver chip is connected to a control terminal of the first switch; a second output terminal of the driver chip is connected to a control terminal of the second switch; an input terminal of the first switch is connected to a power supply; an input terminal of the second switch is grounded; an output terminal of the first switch and an output terminal of the second switch are both connected to a first terminal of the output inductor; a second terminal of the output inductor, as the output terminal of the power supply circuit, is connected to the power terminal of the audio amplifier; and the output capacitor is connected in series between the input terminal of the second switch and the second terminal of the output inductor; and
wherein the driver chip comprises a second operational amplifier, a comparator, a driver, and an inverter that are successively connected.

18. (canceled)

19. The audio processing circuit according to claim 1, further comprising a filter circuit, connected between the input terminal of the audio amplifier and the feedback control circuit; and
wherein the filter circuit is configured to filter the audio signal and transmit a filtered audio signal to the feedback control circuit; and
wherein the filter circuit comprises a second-order Butterworth low-pass filter.

20. (canceled)

21. The audio processing circuit according to claim 1, wherein the audio amplifier is a digital amplifier chip comprising a switch amplifier.

22. The audio processing circuit according to claim 1, wherein the controller comprises a microcontroller unit.

23. An audio playback module, comprising: an audio playback assembly, and the audio processing circuit as defined in claim 1; and
wherein the audio processing circuit is connected to the audio playback assembly, and is configured to drive the audio playback assembly to play audio.

24. An electronic device, comprising a device body, and the audio playback module as defined in claim 23 that is arranged in the device body.
